(19) United States
(12) Patent Application Publication
(10) Pub. No.: US 2023/0404147 A1
(43) Pub. Date: Dec. 21, 2023

(54) AEROSOL GENERATOR WITH CURVED CHAMBER

(71) Applicant: Philip Morris Products S.A., Neuchâtel (CH)

(72) Inventors: Jakub BIALEK, Peseux (CH); Leander DITTMANN, Leander (CH); Mahdi ASGARI, Zurich (CH)

(73) Assignee: Philip Morris Products S.A., Neuchâtel (CH)

(21) Appl. No.: 18/248,449

(22) PCT Filed: Oct. 14, 2021
(86) PCT No.: PCT/EP2021/078538

§ 371 Date: Apr. 10, 2023

(30) Foreign Application Priority Data
Oct. 16, 2020 (EP) 20202422.0

(51) Int. Cl. A24F 40/05; A24F 40/485; A24F 40/10; A24F 40/50; A24F 40/42

(52) U.S. Cl. CPC A24F 40/05; A24F 40/485; A24F 40/42; A24F 40/50; A24F 40/10

(57) ABSTRACT

An aerosol generator configured to generate an aerosol from an aerosol-forming substrate is provided, the aerosol generator including: a non-thermal aerosol-generating element configured to aerosolise an aerosol-forming substrate; at least one air inlet; at least one air outlet; a chamber between the air inlet and the air outlet, the non-thermal aerosol-generating element being arranged in the chamber and being further configured to release aerosolised aerosol-forming substrate into the chamber; an airflow path extending through the chamber between the air inlet and the air outlet, via the non-thermal aerosol-generating element; and a side wall circumscribing the non-thermal aerosol-generating element, the side wall having a curved surface defining a curved surface of the chamber, the air inlet extending through the side wall and being configured to direct air into the chamber in a direction tangential to the curved surface of the chamber.

The present disclosure relates to an aerosol generator, an aerosol-generating system comprising an aerosol generator and a cartridge comprising an aerosol generator.

Aerosol-generating systems comprising aerosol generators that are configured to generate an aerosol from an aerosol-forming substrate are generally known in the art. Often such aerosol-generating systems generate an inhalable aerosol for inhalation by a user. Some known aerosol generators utilise heat to vaporise an aerosol-forming substrate, with the vaporised aerosol-forming substrate cooling to form an aerosol. Other aerosol generators use non-thermal means to aerosolise a liquid aerosol-forming substrate. For example, some known non-thermal aerosol-generators use a vibrating mesh to aerosolise a liquid aerosol-forming substrate, and some known non-thermal aerosol-generators use surface acoustic waves to aerosolise a liquid aerosol-forming substrate.

It has been found that once an aerosol has been generated by an aerosol generator, aerosol droplets may come into contact with surfaces of an aerosol generator and be deposited on the surfaces, preventing delivery of the deposited aerosol droplets to a user. In particular, deposition of aerosol droplets on surfaces of an aerosol generator has been found to be a particular problem in non-thermal aerosol generators, in which the aerosolised liquid aerosol-forming substrate may tend to be comprised of larger droplets than the vapour generated by heated aerosol-forming substrates. Larger aerosol droplets have a greater tendency to be deposited on surfaces of an aerosol generator before delivery to a consumer. Likewise, non-thermal aerosol generators may be configured to generate aerosol droplets without any air flowing through or along the non-thermal aerosol-generator. The absence of airflow when the aerosol droplets are generated may cause the aerosol droplets to be deposited on surfaces of an aerosol generator.

It would be desirable to provide an aerosol generator that reduces the likelihood of deposition of aerosol droplets on surfaces of the generator before delivery of the aerosol to a consumer.

According to the present disclosure, there is provided an aerosol generator configured to generate an aerosol from an aerosol-forming substrate. The aerosol generator may comprise an aerosol-generating element configured to aerosolise an aerosol-forming substrate. The aerosol generator may comprise at least one air inlet and at least one air outlet. The aerosol generator may comprise a chamber between the at least one air inlet and the at least one air outlet. The aerosol-generating element may be arranged in the chamber and configured to release aerosolised aerosol-forming substrate into the chamber. The aerosol generator may further comprise an airflow path extending through the chamber between the at least one air inlet and the at least one air outlet, via the aerosol-generating element.

According to a preferred embodiment of the present disclosure, there is provided an aerosol generator configured to generate an aerosol from an aerosol-forming substrate. The aerosol generator may comprise an aerosol-generating element configured to aerosolise an aerosol-forming substrate. The aerosol-generator may further comprise at least one air inlet and at least one air outlet. The aerosol-generator may further comprise a chamber between the at least one air inlet and the at least one air outlet. The aerosol-generating element may be arranged in the chamber and configured to release aerosolised aerosol-forming substrate into the chamber. The aerosol generator may further comprise an airflow path extending through the chamber between the air inlet and the at least one air outlet, via the aerosol-generating element. The aerosol generator may further comprise a side wall circumscribing the aerosol-generating element. The side wall may have a curved surface defining a curved surface of the chamber. The at least one air inlet may extend through the side wall. The at least one air inlet may be configured to direct air into the chamber in a direction tangential to the curved surface of the chamber.

It has been found that providing an aerosol generator with a curved surface and directing air into the chamber in a direction tangential to the curved surface may advantageously reduce deposition of aerosol droplets and particles on surfaces of the aerosol generator. Reducing deposition of aerosol droplets on surfaces of an aerosol generator may improve the consistency of the delivery of aerosol to a user. It may also reduce undesired accumulation of liquid on surfaces of the aerosol generator. The reduction of undesired accumulation of liquid on surfaces of the aerosol generator may reduce leakage from the aerosol generator.

Providing an aerosol generator with a curved surface and directing air into the chamber in a direction tangential to the curved surface may cause air entering the chamber through the at least one air inlet to follow the curved surface of the chamber, forming a pocket of air swirling along the periphery of the chamber. The inventors have realised that such a pocket of air swirling along the periphery of the chamber may be used to wrap around the aerosol generated by the aerosol-generating element and direct the generated aerosol away from the surfaces of the chamber. By directing the generated aerosol away from the surfaces of the chamber, the amount of aerosol deposited on the surfaces of the chamber can be greatly reduced.

In particularly preferred embodiments, the aerosol-generating element is a non-thermal aerosol-generating element. It has been found that providing an aerosol generator with a curved surface and directing air into the chamber in a direction tangential to the curved surface may be particularly effective at reducing deposition of generated aerosol on the surfaces of the aerosol generator for aerosol generators with non-thermal aerosol-generating elements. This is because the aerosol droplets generated by non-thermal aerosol-generating elements may tend to be larger than the droplets generated by thermal aerosol-generating elements, and larger aerosol droplets have a greater tendency to be deposited on the surfaces of an aerosol generator. Likewise, non-thermal aerosol generators may be configured generate aerosol droplets without any air flowing through or along the non-thermal aerosol-generator. The absence of airflow when the aerosol droplets are generated may also cause the aerosol droplets to be deposited on surfaces of an aerosol generator.

According to another preferred embodiment of the present disclosure, there is provided an aerosol generator configured to generate an aerosol from an aerosol-forming substrate. The aerosol generator may comprise a planar aerosol-generating element configured to aerosolize an aerosol-forming substrate. The planar aerosol-generating element may extend substantially in a plane. The aerosol-generator may further comprise at least one air inlet and at least one air outlet. The aerosol-generator may further comprise a chamber between the at least one air inlet and the at least one air outlet. The planar aerosol-generating element may be arranged in the chamber and configured to release aerosolized aerosol-forming substrate into the chamber. The aerosol generator may further comprise an airflow path extending through the chamber between the air inlet and the at least one air outlet, via the planar aerosol-generating element. The aerosol generator may further comprise a side wall circumscribing the aerosol-generating element. The side wall may have a surface defining a surface of the chamber. The at least one air inlet may extend through the side wall. The at least one air inlet may be configured to direct air into the chamber in a direction away from the plane of the planar aerosol-generating element. The at least one air inlet may be configured to direct air in a direction between the plane of the planar aerosol-generating element and the at least one air outlet.

It has been found that directing airflow into the chamber away from a planar aerosol-generating element and toward the opening may improve aerosol generation from the aerosol-generating element. Advantageously, airflow in the chamber in a direction away from the planar aerosol-generating element may encourage aerosol generated from the aerosol-generating element to move away from the aerosol-generating element and may reduce backward flow of the aerosol towards the aerosol-generating element. It has been found that backward flow of aerosol generated from the aerosol-generating element toward the aerosol-generating element can disrupt aerosol generation, resulting in one or more of a reduced rate of aerosol generation and generation of aerosol with different, less desirable characteristics.

According to another preferred embodiment of the present disclosure, there is provided and aerosol generator configured to generate an aerosol from an aerosol-forming substrate. The aerosol generator may comprise a planar aerosol-generating element configured to aerosolise an aerosol-forming substrate. The aerosol generator may further comprise a planar ancillary element coupled to the aerosol-generating element. The aerosol generator may further comprise at least one air inlet extending through the planar ancillary element. The planar aerosol-generating element and the planar ancillary element may extend substantially in the same plane. The at least one air inlet may be configured to direct air in a direction away from the plane.

As mentioned above, it has been found that directing airflow into the chamber away from a planar aerosol-generating element may improve aerosol generation from the aerosol-generating element. Advantageously, airflow in a direction away from the planar aerosol-generating element may encourage aerosol generated from the aerosol-generating element to move away from the aerosol-generating element and may reduce backward flow of the aerosol towards the aerosol-generating element.

In preferred embodiments comprising a chamber between at least one air inlet and at least one air outlet, the at least one air inlet and the chamber may be configured to direct air to rotate or swirl along the periphery of the chamber. Preferably, at least one air inlet is configured to direct air along a periphery of the chamber. The at least one air inlet may be arranged to direct air tangentially into the chamber.

In some embodiments, the chamber extends along a central longitudinal axis. In these embodiments, the chamber may be substantially symmetrical about the central longitudinal axis. The at least one air inlet may be configured to direct air into the chamber in a direction that does not intersect with the central longitudinal axis of the chamber. The at least one air inlet may be configured to direct air into the chamber in a direction around the central longitudinal axis of the chamber.

Advantageously, directing air into the chamber in a direction that causes rotation of the air along the periphery of the chamber, around an axis of rotation, may reduce deposition of aerosol droplets on the surfaces of the chamber.

In some preferred embodiments, the aerosol generator comprises a side wall circumscribing the aerosol-generating element and having a surface defining a surface of the chamber. The at least one air inlet may extend through the side wall. In some embodiments, the surface of the side wall is a curved surface and defines a curved surface of the chamber.

The at least one air inlet may be configured to direct air into the chamber in a direction tangential to the curved surface of the chamber. The at least one air inlet may be configured to direct air into the chamber in a direction angled from a tangent to the curved surface at an angle of between: 0 degrees and 90 degrees; or 0 degrees and 80 degrees; or 0 degrees and 70 degrees; or 0 degrees and 60 degrees; or 0 degrees and 50 degrees; or 0 degrees and 40 degrees; or 0 degrees and 30 degrees; or 0 degrees and 20 degrees; or 0 degrees and 100 degrees. In some embodiments, the chamber extends along a central longitudinal axis, and the at least one air inlet and the surface of the chamber are configured to direct air around the central longitudinal axis of the chamber. In some embodiments, the at least one air inlet may be configured to direct air into the chamber in a direction between the tangent of the curved surface and a central longitudinal axis of the chamber.

The chamber may comprise a mouth end. The at least one air outlet may be arranged at or towards the mouth end. The chamber may comprise an aerosol-generation end. The aerosol-generating element may be arranged at or towards the aerosol-generation end. The at least one air inlet may be arranged towards the aerosol-generation end. The aerosol-generation end may be opposite the mouth end.

The aerosol-generating element may form a surface of the chamber. The aerosol-generating element may define a surface at the aerosol-generation end of the chamber.

In embodiments comprising a side wall defining a surface of the chamber, the at least one air inlet may extend through the side wall at a position towards the aerosol-generation end of the chamber. The side wall may circumscribe the aerosol-generating element. The side wall may extend between the mouth end and the aerosol-generation end. The side wall may extend between the aerosol-generating element at the aerosol-generation end and the at least one air outlet at the mouth end. The at least one air inlet may extend through the side wall.

The chamber may have any suitable shape and size.

In some embodiments, the surface of the side wall defines a tapered chamber. For example, the width of the chamber at the mouth end may be less than a width of the chamber at the aerosol-generation end. This may allow for an aerosol generator in which the width of the aerosol-generating element is greater than the width of a mouth end opening. In some embodiments in which the aerosol-generating element is provided with an airflow when the aerosol droplets are generated, the provision of a tapered chamber may be advantageously used to enhance the generation of aerosol.

In some embodiments in which the surface of the side wall defines a tapered chamber, the taper of the chamber may be constant from the aerosol-generation end to the mouth end. In other words, the taper angle of the surface of the side wall relative to the central longitudinal axis of the chamber may be constant from the aerosol-generation end to the mouth end. In other words, the surface of the side wall extends straight in one direction, between the aerosol-generation end and the mouth end. The tapered side wall may define a conical surface of the chamber. The side wall may define a circularly conical surface of the chamber. The side wall may define an elliptically conical surface of the chamber.

In some embodiments in which the surface of the side wall defines a tapered chamber, the taper of the chamber may vary from the aerosol-generation end to the mouth end. In other words, the taper angle of the surface of the side wall relative to the central longitudinal axis of the chamber may vary from the aerosol-generation end to the mouth end. Advantageously, varying the taper of the chamber from the aerosol-generation end to the mouth end may further reduce deposition of aerosol droplets on the surfaces of the chamber.

In some embodiments, the taper of the chamber or the taper angle of the surface of the side wall may increase from the aerosol-generation end to the mouth end. In other words, the side wall may define a concave surface of the chamber. In these embodiments, the side wall may define a domed surface of the chamber.

In some embodiments, the taper of the chamber or the taper angle of the surface of the side wall may decrease from the aerosol-generation end to the mouth end. In these embodiments, the side wall may define a convex surface of the chamber. In these embodiments, the side wall may define a horn shaped surface of the chamber.

In some embodiments, the surface of the side wall defines a cylindrical chamber. The width of the chamber at the mouth end may be the same as the width of the chamber at the aerosol-generation end. The surface of the side wall may define a circularly cylindrical surface of the chamber. The surface of the side wall may define an elliptically cylindrical surface of the chamber.

In some embodiments, at least one air guide may be provided on the surface of the chamber. The at least one air guide may direct airflow in the chamber along the periphery of the chamber. The at least one air guide may direct airflow in the chamber along the circumference of the chamber. The at least one air guide may direct airflow in the chamber towards the at least one air outlet. The at least one air guide may direct airflow in the chamber away from the aerosol-generating element. Providing one or more air guides on the surface of the chamber may improve rotation of the air along the periphery of the chamber, about an axis of rotation, and further reduce deposition of aerosol droplets on the surfaces of the chamber.

The aerosol-generating element may take any suitable form depending on the type of aerosol-generating element that is required. The aerosol-generating element may comprise, for example, a mesh, flat spiral coil, fibres or a fabric. In some embodiments, the aerosol-generating element may comprise a sheet or a strip.

In some embodiments, the aerosol-generating element is a thermal aerosol-generating element. As used herein, the term “thermal aerosol-generating element” describes an aerosol-generating element that is configured to generate an aerosol from an aerosol-forming substrate by heating. A thermal aerosol-generating element may be a resistive heater. A thermal aerosol-generating element may be a susceptor that is heatable by penetration with an alternating magnetic field. A thermal aerosol-generating element may be an aerosol-forming substrate configured to be heated by absorbing energy from an electromagnetic field applied to the substrate.

The thermal aerosol-generating element may be an internal heater. An internal heater is configured to heat an aerosol-forming substrate from within the aerosol-forming substrate. The thermal aerosol-generating element may be configured to penetrate an aerosol-forming substrate.

For example, the thermal aerosol-generating element may take the form of a blade or a pin configured to penetrate an aerosol-forming substrate.

The thermal aerosol-generating element may be an external heater. An external heater is configured to heat an aerosol-forming substrate from an outer surface of the aerosol-forming substrate.

The thermal aerosol-generating element may take the form of a coil, or a mesh.

In some preferred embodiments, the aerosol-generating element is a non-thermal aerosol-generating element. As used herein, the term “non-thermal aerosol-generating element” describes an aerosol-generating element that is configured to generate an aerosol from an aerosol-forming substrate by means other than heating.

The aerosol-generating element may be any suitable type of non-thermal aerosol-generating element.

In some embodiments, the non-thermal aerosol-generating element is a mesh. The mesh aerosol-generating element may have a plurality of interstices, passages or nozzles. The plurality of interstices, passages or nozzles may have a tapered shape along their length. The plurality of interstices, passages or nozzles may have a conical shape along their length.

In some preferred embodiments, the mesh aerosol-generating element may be a vibratable mesh element that is configured to be oscillated. The mesh aerosol-generating element may be configured to aerosolise aerosol-forming substrate when the vibratable mesh element is oscillated. Liquid aerosol-forming substrate may pass through the nozzles of the vibratable mesh element when the vibratable mesh element is oscillated. Liquid aerosol-forming substrate may be aerosolised as it passes through the nozzles of the vibratable mesh element when the vibratable mesh element is oscillated.

In these embodiments, the aerosol generator may further comprise an actuator coupled to the mesh aerosol-generating element. The actuator may be configured to oscillate the mesh aerosol-generating element.

The actuator may be any type of actuator for exciting vibrations in the mesh aerosol-generating element. The actuator may comprise a piezoelectric transducer. The piezoelectric transducer may provide actuator that is sufficiently small, lightweight and easy to control for use in a handheld aerosol-generating system.

The piezoelectric transducer may comprise a monocrystalline material. The piezoelectric transducer may comprise quartz. The piezoelectric transducer may comprise a ceramic. The ceramic may comprise barium titanate (BaTiOs). The ceramic may comprise lead zirconate titanate (PZT). The ceramic may include doping materials such as Ni, Bi, La, Nd or Nb ions. The piezoelectric transducer may be polarised. The piezoelectric transducer may be unpolarised. The piezoelectric transducer may comprise both polarised and unpolarised piezoelectric materials.

The actuator may be arranged at any suitable location with respect to the mesh aerosol-generating element. The actuator may be arranged to transmit vibrations to the mesh aerosol-generating element at an inlet side or an outlet side of the mesh aerosol-generating element. The actuator may be arranged to transmit vibrations to the mesh aerosol-generating element at an inlet side. The actuator may be arranged to transmit vibrations to the mesh aerosol-generating element at an outlet side. The actuator may be in direct contact with the mesh aerosol-generating element. The actuator may be secured to the mesh aerosol-generating element. The actuator may be secured to the mesh aerosol-generating element by pressure. The actuator may be bonded to the mesh aerosol-generating element. A transfer member may be provided between the actuator and the mesh aerosol-generating element to transfer vibrations from the actuator to the vibratable element.

The actuator may comprise at least one actuating element. The at least one actuating element may be any suitable shape. The at least one actuating element may be substantially circular or elliptical. The at least one actuating element may be substantially triangular, square or any regular or irregular shape. The at least one actuating element may be annular. The at least one actuating element may substantially circumscribe the mesh aerosol-generating element.

The at least one actuating element may be planar. The at least one planar actuating element may extend substantially in a plane. Preferably, in embodiments in which the mesh aerosol-generating element is planar, the at least one actuating element is planar. In embodiments in which the mesh aerosol-generating element is planar and the at least one actuating element is planar, the at least one actuating element extends in substantially the same plane as the mesh aerosol-generating element.

In some particularly preferred embodiments, the mesh aerosol-generating element is planar, extending in a plane and having a circular cross-section, and the at least one actuating element is planar, extending in substantially the same plane as the mesh aerosol-generating element and circumscribing the mesh aerosol-generating element.

The actuator may be configured to oscillate the vibratable element at a predetermined frequency. The predetermined frequency may be between about 20 kHz and about 1500 kHz, or between about 50 kHz and about 1000 kHz, or between about 100 kHz and about 500 kHz. This may provide a desired aerosol-output rate and a desired droplet size for a good user experience.

In some preferred embodiments in which the non-thermal aerosol-generating element is a mesh aerosol-generating element, the mesh aerosol-generating element may not be configured to be vibrated. In these embodiments, the mesh aerosol-generating element may be arranged in an oscillation chamber. The oscillation chamber may comprise a cavity configured to contain a liquid aerosol-forming substrate to be aerosolised. The oscillation chamber may further comprise a liquid inlet for providing a supply of the liquid to be aerosolised to the cavity. The oscillation chamber may further comprise an elastically deformable element and an actuator arranged to oscillate the elastically deformable element. Oscillation of the elastically deformable element by the actuator may vary the pressure inside the cavity. Oscillation of the elastically deformable element may vary the pressure of the liquid contained within the cavity, causing the liquid within the cavity to pass through the mesh aerosol-generating element and be aerosolised.

The actuator may be a piezoelectric transducer, as described above.

The actuator may be configured to oscillate the elastically deformable element at any suitable frequency. For example, the actuator may be configured to oscillate the elastically deformable element at a frequency of between about 0.05 MHz and about 10.0 MHz, between about 0.1 MHz and about 5.0 MHz, between about 0.2 MHz and about 4.5 MHz, between about 0.3 MHz and about 3 MHz, between about 0.4 MHz and about 2.5 MHz or between about 0.5 MHz and about 2 MHz. The actuator may be configured to oscillate the elastically deformable element at a frequency to achieve resonance of the oscillation system.

In some embodiments, the non-thermal aerosol-generating element may be part of a surface acoustic wave atomizer (SAW-atomiser). A SAW atomiser uses surface acoustic waves to atomise a liquid aerosol-forming substrate. The term “surface acoustic wave” is used herein to include Rayleigh waves, Lamb waves and Love waves.

The SAW-atomiser comprises a substrate comprising an active surface. The aerosol-generating element may form the substrate comprising the active surface.

The SAW-atomiser may further comprise at least one transducer positioned on the active surface of the substrate for generating surface acoustic waves on the active surface of the substrate.

In use, power may be provided to the SAW-atomizer activating the at least one transducer to produce surface acoustic waves (Rayleigh-waves) that propagate along the active surface. The energy of the surface acoustic waves may be transferred to a liquid aerosol-forming substrate that is supplied to an atomisation region of the active surface. The energy supplied to the liquid aerosol-forming substrate causes the formation of aerosol droplets of the liquid aerosol-forming substrate, atomising the liquid aerosol-forming substrate in the atomization region. The surface acoustic waves transferred into the liquid destabilize droplets on an open surface of the liquid such that the surface of the droplet breaks up and forms a mist of aerosol droplets.

As a SAW-atomizer, commonly known SAW-sensor chips may be used. SAW-sensor chips typically comprise at least one interdigital (or interdigitated) transducer comprising electrodes arranged on a piezoelectric substrate, for example, printed onto the substrate. An AC voltage applied to the individual ‘fingers’ of the transducer electrodes cause the piezoelectric substrate to mechanically deform due to alternating regions of tensile and compressive strain in the piezoelectric substrate created between the fingers. As fingers on the same side of the transducer are at the same level of compression or tension, the space between them (known as pitch of the transducer) corresponds to the wavelength of the mechanical wave. The generated waves typically have nanometre size amplitudes and propagate along the surface of the piezoelectric substrate at frequencies within the megahertz range.

The at least one transducer of the SAW-atomizer may be an interdigital transducer comprising electrodes arranged on a piezoelectric substrate. A transducer may comprise a reflector to improve directionality of the generated surface acoustic waves. The transducer may be configured to generate parallel waves, for example, by an array of straight electrodes arranged in parallel. The transducer may be configured to have a focussing effect on the generated waves. For example, the transducer may be provided with electrodes having parallel but curved shapes such as to focus the generated wave to a small zone. Preferably, the transducer comprises a reflector and has a focussing effect.

The SAW-atomiser may be configured to generate surface acoustic waves at a predetermined frequency. The predetermined frequency may be about 20 MHz or higher, may for example be between about 20 MHz and about 100 MHz, or between about 20 MHz and about 80 MHz. This may provide a desired aerosol output rate and a desired droplet size for a good user experience.

In some embodiments, the non-thermal aerosol-generating element comprises one or more of the following elements: an impinging jet, a rotating disk, a spray nozzle, a flow focussing/blurring device and a collision atomiser.

In some preferred embodiments, the aerosol-generating element is a planar aerosol-generating element. The planar aerosol-generating element extends substantially in a plane. The planar element may extend in a plane.

The planar aerosol-generating element may be arranged in any suitable manner in the chamber of the aerosol generator.

In some embodiments, the chamber extends along a central longitudinal axis, and the plane of the planar aerosol-generating element is parallel to the central longitudinal axis of the chamber.

In some preferred embodiments, the chamber extends along a central longitudinal axis, and the plane of the planar aerosol-generating element is perpendicular to the central longitudinal axis of the chamber. In some embodiments in which the chamber comprises a mouth end, and the at least one air outlet is arranged at the mouth end, the planar aerosol-generating element is arranged such that a major surface of the aerosol-generating element, through which aerosol is generated, faces the mouth end.

In some embodiments, the at least one air inlet is arranged to direct air in a direction parallel to the plane of the planar aerosol-generating element.

In some preferred embodiments, the at least one air inlet may be arranged to direct air into the chamber in a direction away from the plane of the planar aerosol-generating element. The at least one air inlet is arranged to direct air in a direction angled from the plane of the planar aerosol-generating element at an angle of between: 0 degrees and 90 degrees; or 5 degrees and 85 degrees; or 10 degrees and 80 degrees; or 15 degrees and 75 degrees; or 20 degrees and 70 degrees; or 25 degrees and 65 degrees; or 30 degrees and 60 degrees; or 65 degrees and 85 degrees; or 70 degrees and 80 degrees.

The at least one air inlet may be arranged to direct air in a direction between the plane of the planar aerosol-generating element and the at least one air outlet.

The aerosol-generating element may be thin. In other words, the aerosol-generating element may have a thickness dimension that is substantially smaller than the width and length dimensions of the aerosol-generating element.

At least a portion of the aerosol-generating element may be fluid permeable. In some embodiments, the aerosol-generating element is fluid permeable. As used herein a “fluid permeable” element means an element that allows liquid or gas to permeate through it. The aerosol-generating element may have a plurality of openings formed in it to allow fluid to permeate through it. In particular, the aerosol-generating element may allow the aerosol-forming substrate, in either gaseous phase or both gaseous and liquid phase, to permeate through it.

In some preferred embodiments, the aerosol-generating element may comprise a mesh. The aerosol-generating element may comprise an array of filaments forming a mesh. As used herein the term “mesh” encompasses grids and arrays of filaments having spaces therebetween. The term mesh also includes woven and non-woven fabrics.

The filaments may define interstices between the filaments and the interstices may have a width of between 10 micrometres and 100 micrometres. Preferably the filaments give rise to capillary action in the interstices, so that in use, the source liquid is drawn into the interstices, increasing the contact area between the aerosol-generating element and the liquid.

The filaments may form a mesh of size between 160 and 600 Mesh US (+/−10%) (i.e. between 160 and 600 filaments per inch (+/−10%)). The width of the interstices may be between 35 micrometres and 140 micrometres, or between 25 micrometres and 75 micrometres. For example, the width of the interstices may be 40 micrometres, or 63 micrometres. The percentage of open area of the mesh, which is the ratio of the area of the interstices to the total area of the mesh is preferably between 25 and 56%. The mesh may be formed using different types of weave or lattice structures. Alternatively, the filaments consist of an array of filaments arranged parallel to one another.

The filaments may be formed by etching a sheet material, such as a foil. This may be particularly advantageous when the heater assembly comprises an array of parallel filaments. If the heating element comprises a mesh or fabric of filaments, the filaments may be individually formed and knitted together.

Preferably, the mesh is sintered. The filaments of the mesh may be sintered together. Advantageously, sintering the mesh creates electrical bonds between filaments extending in different directions. In particular, where the mesh comprises one or more of woven and non-woven fabrics, it is advantageous for the mesh to be sintered to create electrical bonds between overlapping filaments.

The mesh may also be characterised by its ability to retain liquid, as is well understood in the art.

The filaments of the mesh may have a diameter of between 8 micrometres and 100 micrometres, between 30 micrometres and 100 micrometres, between 8 micrometres and 50 micrometres, or between 8 micrometres and 39 micrometres. The filaments of the mesh may have a diameter of 50 micrometres.

The filaments of the mesh may have any suitable cross-section. For example, the filaments may have a round cross section or may have a flattened cross-section.

Preferably, the aerosol generator comprises at least one air inlet. The at least one air inlet may be configured to direct air into the chamber of the aerosol generator. Where the aerosol generator comprises a side wall defining a surface of the chamber, the at least one air inlet may extend through the side wall.

The at least one air inlet may have any suitable cross-sectional shape. For example, the at least one air inlet may have one of: a circular cross-section; an elliptical cross-section; a square cross-section; a rectangular cross-section; and a triangular cross-section. The at least one air inlet may have a polygonal cross-section.

The at least one air inlet may have a total cross-sectional area of between: 0.5 square millimetres and 30 square millimetres; or 2 square millimetres and 25 square millimetres; or 5 square millimetres and 20 square millimetres; or 5 square millimetres and 20 square millimetres; or square millimetres and 15 square millimetres. Such a total cross-sectional area may enable the at least one air inlet to direct a desirable rate of air flow into the chamber.

The at least one air inlet may comprise a plurality of air inlets. The at least one air inlet may comprise any suitable number of air inlets. For example, the at least one air inlet may comprise two, three, four, five, six, seven, eight or nine air inlets. The at least one air inlet may comprise any suitable number of air inlets to provide the desired rate of airflow into the chamber. The plurality of air inlets may have a total cross-sectional area of between: 2 square millimetres and 30 square millimetres; or 2 square millimetres and 25 square millimetres; or 5 square millimetres and 20 square millimetres; or 5 square millimetres and 20 square millimetres; or 5 square millimetres and 15 square millimetres.

The plurality of air inlets may be spaced around the circumference of the aerosol-generating element.

In some embodiments in which the chamber extends along a central longitudinal axis, the plurality of air inlets are located at different positions along the central longitudinal axis of the chamber. In some embodiments in which the chamber extends along a central longitudinal axis, the plurality of air inlets are located at the same position along the central longitudinal axis of the chamber.

In some preferred embodiments, all of the air inlets have the same cross-sectional shape. In some preferred embodiments, all of the air inlets have the same cross-sectional area. The air inlets may have different cross-sectional shapes. The air inlets may have different cross-sectional areas.

In some preferred embodiments, the at least one air inlet comprises two air inlets, a first air inlet and a second air inlet. The first air inlet may be configured to direct air in the chamber in a first direction, and the second air inlet may be configured to direct air in the chamber in a second direction, different to the first direction. The first air inlet may be configured to direct air in the chamber in a first direction, and the second air inlet may be configured to direct air in the chamber in a second direction, opposite to the first direction. The first air inlet may be arranged at a first side of the chamber, and the second air inlet may be arranged at a second side of the chamber, opposite the first side.

In some embodiments in which the chamber extends along a central longitudinal axis, the first air inlet and the second air inlet are located at the same position along the longitudinal axis. In some embodiments in which the chamber extends along a central longitudinal axis, the first air inlet is arranged at a first position along the longitudinal axis and the second air inlet is arranged at a second position along the longitudinal axis, different to the first position.

The at least one air inlet may be formed by an air passage. The air passage may have a length and a cross-sectional area. The air passage forming the at least one air inlet may extend between an external surface of the aerosol generator and a surface defining the chamber.

The air passage forming the at least one air inlet may have a cross-section at the surface defining the chamber. The air passage forming the at least one air inlet may have a length. The length of the air passage may be greater than the dimensions of the cross-section of the air inlet at the surface of the chamber. For example, where an air passage has a circular cross-section at the surface of the chamber, the length of the air passage may be greater than the diameter of the cross-section of the passage at the surface of the chamber. Advantageously, configuring the air passage forming the air inlet such that the length of the passage is greater than the cross-section of the passage may improve the directionality of air flowing into the chamber through the air passage into the chamber.

Where the at least one air inlet comprises a plurality of air inlets, each air inlet may be formed by a different air passage. The aerosol generator may comprise a plurality of air passages.

In some preferred embodiments, the at least one air inlet is configured to direct air into the chamber in a direction away from the aerosol-generating element.

Preferably, the at least one air inlet is configured to direct air into the chamber in a direction that does not intersect with the aerosol-generating element. The at least one air inlet may be configured to direct air into the chamber in a direction at least partially towards the at least one air outlet. In some embodiments in which the chamber comprises a mouth end and the at least one air outlet is arranged at the mouth end, the at least one air inlet may be configured to direct air into the chamber in a direction at least partially towards the mouth end.

In embodiments in which the chamber extends along a central longitudinal axis, the at least one air inlet may be arranged to direct air into the chamber in a direction that is not perpendicular to the central longitudinal axis. The at least one air inlet may be arranged to direct air into the chamber in a direction that is angled from the central longitudinal axis at an angle of between: 1 degree and 89 degrees; or 5 degrees and 85 degrees; or 10 degrees and 80 degrees; or 15 degrees and 75 degrees; or 20 degrees and 70 degrees; or 25 degrees and 65 degrees; or 30 degrees and 60 degrees.

Preferably, the aerosol generator comprises at least one air outlet. The at least one air outlet may be configured to direct air out of the chamber of the aerosol generator. Where the aerosol generator comprises a chamber having a mouth end, the at least one air outlet may be arranged at the mouth end of the chamber.

The at least one air outlet may have any suitable cross-sectional shape. For example, the at least one air outlet may have one of: a circular cross-section; an elliptical cross-section; a square cross-section; a rectangular cross-section; and a triangular cross-section. The at least one air outlet may have a polygonal cross-section.

The at least one air outlet may have a total cross-sectional area of between: 2 square millimetres and 30 square millimetres; or 2 square millimetres and 25 square millimetres; or 5 square millimetres and 20 square millimetres; or 5 square millimetres and 20 square millimetres; or square millimetres and 15 square millimetres. Such a total cross-sectional area may enable the at least one air outlet to direct a desirable rate of air flow out of the chamber.

The at least one air outlet may comprise a plurality of air outlets. The at least one air outlet may comprise any suitable number of air outlets. For example, the at least one air outlet may comprise two, three, four, five, six, seven, eight or nine air outlets. The at least one air outlet may comprise any suitable number of air outlets to provide the desired rate of airflow out of the chamber. The plurality of air outlets may have a total cross-sectional area of between: 0.5 square millimetres and 30 square millimetres; or 2 square millimetres and 25 square millimetres; or 5 square millimetres and 20 square millimetres; or 5 square millimetres and 20 square millimetres; or square millimetres and 15 square millimetres.

The aerosol generator may comprise a chamber between the at least one air inlet and the at least one air outlet. The aerosol generator may further comprise an airflow path extending through the chamber between the at least one air inlet and the at least one air outlet. The airflow path may extend through the chamber between the at least one air inlet and the at least one air outlet, via the aerosol-generating element.

In some preferred embodiments, the aerosol generator comprises an ancillary element coupled to the aerosol-generating element.

The aerosol generator may further comprise at least one air inlet extending through the ancillary element. The at least one air inlet may have any suitable cross-sectional shape. For example, the at least one air inlet may have one of a circular, elliptical, square, rectangular or triangular cross-sectional shape. The at least one air inlet may have a polygonal cross-sectional shape. The at least one air inlet may form a slot through the ancillary element.

The at least one air inlet may comprise a plurality of air inlets. The plurality of air inlets may comprise any suitable number of air inlets. For example, the plurality of air inlets may comprise two, three, four, five, six, seven, eight or nine air inlets. The plurality of air inlets may be spaced around the circumference of the ancillary element. Preferably, the ancillary element circumscribes the aerosol-generating element and the plurality of air inlets are spaced around the circumference of the ancillary element. In some embodiments, the plurality of air inlets have different cross-sectional shapes. In some embodiments, the plurality of air inlets have identical cross-sectional shapes. In some embodiments, the plurality of air inlets have different cross-sectional areas. In some embodiments, the plurality of air inlets have identical cross-sectional areas.

In some particularly preferred embodiments, the aerosol generator comprises a planar aerosol-generating element and a planar ancillary element coupled to the planar aerosol-generating element. In these particularly preferred embodiments, the planar aerosol-generating element and the planar ancillary element may extend in substantially the same plane.

In these particularly preferred embodiments, the at least one air inlet may be configured to direct air in a direction away from the plane. Preferably, the at least one air inlet is configured to direct air in a direction perpendicular to the plane. The at least one air inlet may extend through the planar ancillary element in a direction perpendicular to the plane. The at least one air inlet may be configured to direct air in a direction between the plane and a direction perpendicular to the plane. The at least one air inlet may extend through the planar ancillary element in a direction between the plane and a direction perpendicular to the plane. The at least one air inlet may be configured to direct air in a direction angled to the plane at an angle of between: 1 degree and 89 degrees; or 5 degrees and 85 degrees; or 10 degrees and 80 degrees; or 15 degrees and 75 degrees; or 20 degrees and 70 degrees; or 25 degrees and 65 degrees; or 30 degrees and 60 degrees; or 65 degrees and 85 degrees; or 70 degrees and 80 degrees.

The ancillary element may circumscribe the aerosol-generating element. The planar ancillary element may circumscribe the planar aerosol-generating element.

The ancillary element may comprise a support element. Where the aerosol generator comprises a side wall, the support element may couple the aerosol-generating element to the side wall. Where the aerosol generator forms part of an aerosol-generating device or cartridge, the support element may couple the aerosol-generating element to a housing of the aerosol-generating device or cartridge. The at least one air inlet may extend through the support element.

Preferably, the support element comprises a thermally insulative material. Advantageously, forming the support element from a thermally insulative material may minimise heat transfer from the aerosol-generating element to the support element. Preferably, the aerosol-generating element comprises an electrically insulative material. The support element may be formed from a durable material. The support element may be formed from a liquid impermeable material. The support element may be formed form a mouldable plastics material, such as polypropylene (PP) or polyethylene terephthalate (PET).

The support element may have any suitable shape and size. The support element may be a planar support element. Where the aerosol-generating element is planar, the planar support element may extend in the same plane as the planar aerosol-generating element. The support element may circumscribe the aerosol-generating element.

Where the aerosol-generating element comprises a mesh element, the ancillary element may comprise an actuating element. The actuating element may be coupled to the mesh aerosol-generating element. The actuating element may be configured to oscillate the mesh aerosol-generating element. Preferably, the actuating element is a piezoelectric transducer. The at least one air inlet may extend through the actuating element.

Preferably, the mesh aerosol-generating element is planar and the actuating element is planar, the actuating element extending in the same plane as the mesh aerosol-generating element. The actuating element may circumscribe the mesh aerosol-generating element.

The ancillary element may comprise a support element and an actuating element. The actuating element may be coupled to the aerosol-generating element. The support element may be coupled to the actuating element. The actuating element may circumscribe the aerosol-generating element. The support element may circumscribe the actuating element. The support element may circumscribe the actuating element and the aerosol-generating element.

In some preferred embodiments the at least one air inlet extends through the support element. In some embodiments, the at least one air inlet comprises a plurality of air inlets, at least one of the plurality of air inlets extends through the support element and at least one of the plurality of air inlets extends through the actuating element.

In some preferred embodiments, the ancillary element is a planar element comprising a planar actuating element and a planar support element. In these preferred embodiments, the aerosol-generating element may be planar and the planar ancillary element may extend in the same plane as the planar aerosol-generating element. The aerosol-generating element may have a substantially circular cross-section, the actuating element may form a ring circumscribing the aerosol-generating element and the support element may form a ring circumscribing the actuating element.

According to the present disclosure, there is provided an aerosol-generating system. The aerosol-generating system comprises an aerosol generator as described above. The aerosol-generating system may further comprise a reservoir for holding a liquid aerosol-forming substrate. The aerosol-generating system may further comprise a liquid supply element configured to supply liquid from the reservoir to the aerosol-generating element.

The aerosol-generating system may be a handheld aerosol-generating system configured to allow a user to puff on a mouthpiece to draw an aerosol through a mouth end opening. The aerosol-generating system may have a size comparable to a conventional cigar or cigarette. The aerosol-generating system may have a total length between about 30 mm and about 150 mm. The aerosol-generating system may have an external diameter between about 5 mm and about 30 mm.

The reservoir is configured to hold an aerosol-forming substrate. In particular, the reservoir is configured to hold a liquid aerosol-forming substrate. The reservoir may have any suitable shape and size depending on the requirements of the aerosol-generating system.

The aerosol-generating system may comprise an aerosol-forming substrate. As used herein, the term “aerosol-forming substrate” refers to a substrate capable of releasing volatile compounds that can form an aerosol. Volatile compounds may be released by heating the aerosol-forming substrate. Preferably, the aerosol-generating system contains a liquid aerosol-forming substrate.

The aerosol-forming substrate may be liquid at room temperature and atmospheric pressure. The aerosol-forming substrate may comprise both liquid and solid components. The liquid aerosol-forming substrate may comprise nicotine. The nicotine containing liquid aerosol-forming substrate may be a nicotine salt matrix. The liquid aerosol-forming substrate may comprise plant-based material. The liquid aerosol-forming substrate may comprise tobacco. The liquid aerosol-forming substrate may comprise a tobacco-containing material containing volatile tobacco flavour compounds, which are released from the aerosol-forming substrate upon heating. The liquid aerosol-forming substrate may comprise homogenised tobacco material. The liquid aerosol-forming substrate may comprise a non-tobacco-containing material. The liquid aerosol-forming substrate may comprise homogenised plant-based material.

The liquid aerosol-forming substrate may comprise one or more aerosol-formers. An aerosol-former is any suitable known compound or mixture of compounds that, in use, facilitates formation of a dense and stable aerosol and that is substantially resistant to thermal degradation at the temperature of operation of the system. Examples of suitable aerosol formers include glycerine and propylene glycol. Suitable aerosol-formers are well known in the art and include, but are not limited to: polyhydric alcohols, such as triethylene glycol, 1,3-butanediol and glycerine; esters of polyhydric alcohols, such as glycerol mono-, di- or triacetate; and aliphatic esters of mono-, di- or polycarboxylic acids, such as dimethyl dodecanedioate and dimethyl tetradecanedioate. The liquid aerosol-forming substrate may comprise water, solvents, ethanol, plant extracts and natural or artificial flavours.

The liquid aerosol-forming substrate may comprise nicotine and at least one aerosol-former. The aerosol-former may be glycerine or propylene glycol. The aerosol former may comprise both glycerine and propylene glycol. The liquid aerosol-forming substrate may have a nicotine concentration of between about 0.5% and about 10%, for example about 2%.

The liquid supply element is arranged to supply a liquid aerosol-forming substrate to the aerosol-generating element. Preferably, the liquid supply element is arranged to supply a liquid aerosol-forming substrate from the reservoir to the aerosol-generating element.

The liquid supply element may be in fluid communication with the aerosol-generating element. The liquid supply element may be in fluid communication with the reservoir. The liquid supply element may be configured to transport aerosol-forming substrate from the reservoir to the susceptor element.

The liquid supply element may comprise a capillary material. A capillary material is a material that is capable of transport of liquid from one end of the material to another by means of capillary action. The capillary material may have a fibrous or spongy structure. The capillary material preferably comprises a bundle of capillaries. For example, the capillary material may comprise a plurality of fibres or threads or other fine bore tubes. The fibres or threads may be generally aligned to convey liquid aerosol-forming substrate towards the aerosol-generating element. In some embodiments, the capillary material may comprise sponge-like or foam-like material. The structure of the capillary material may form a plurality of small bores or tubes, through which the liquid aerosol-forming substrate can be transported by capillary action. Where the aerosol-generating element comprises interstices or apertures, the capillary material may extend into interstices or apertures in the susceptor element. The aerosol-generating element may draw liquid aerosol-forming substrate into the interstices or apertures by capillary action. Where the aerosol-generating element forms part of a SAW-atomiser and the aerosol-generating element comprises the substrate with an active surface, the liquid supply element may be arranged to supply liquid to the atomisation region of the active surface. The liquid supply element may comprise a pump.

In some embodiments, the reservoir contains a retention material for holding a liquid aerosol-forming substrate. The retention material may be a foam material, a sponge material or a collection of fibres. The retention material may be formed from a polymer or co-polymer. In some embodiments, the retention material is a spun polymer. The retention material may be formed from any of the materials described above as suitable for the liquid supply element.

Where the aerosol-generating system comprises a liquid supply element and a retention material, the liquid supply element and the retention material may be formed from the same material, or different materials. The retention material may be in fluid communication with the aerosol-generating element. The retention material may contact the aerosol-generating element. The retention material may be in fluid contact with a liquid supply element. The retention material may contact a liquid supply element.

The aerosol-generating system may further comprise a power supply. The power supply may be coupled to the aerosol generator for supplying power to the aerosol generator. The power supply may be coupled to the aerosol-generating element for supplying power to the aerosol generator.

The power supply may be a DC power supply. The power supply may be a battery. The battery may be a Lithium based battery, for example a Lithium-Cobalt, a Lithium-Iron-Phosphate, a Lithium Titanate or a Lithium-Polymer battery. The battery may be a Nickel-metal hydride battery or a Nickel cadmium battery. The power supply may be another form of electrical charge storage device such as a capacitor. The power supply may be rechargeable and be configured for many cycles of charge and discharge. The power supply may have a capacity that allows for the storage of enough energy for one or more user experiences of the aerosol-generating system; for example, the power supply may have sufficient capacity to allow for the continuous generation of aerosol for a period of around six minutes, corresponding to the typical time taken to smoke a conventional cigarette, or for a period that is a multiple of six minutes. In another example, the power supply may have sufficient capacity to allow for a predetermined number of puffs or discrete activations of the atomiser assembly.

The power supply may be configured to store and supply forms of energy different from electrical energy. The power supply may be configured to store and supply mechanical energy. The mechanical energy may be provided or generated by a user.

The aerosol-generating system may further comprise control circuitry.

The control circuitry may comprise a microprocessor. The microprocessor may be a programmable microprocessor, a microcontroller, or an application specific integrated chip (ASIC) or other electronic circuitry capable of providing control.

The control circuitry may be coupled to the power supply. The control circuitry may be coupled to the aerosol generator. The control circuitry may be configured to control the supply of power from the power supply to the aerosol generator. In some embodiments, the control circuitry is configured to control the supply of power from the power supply to the aerosol-generating element of the aerosol-generator. In some embodiments in which the aerosol generator comprises an actuator, the control circuitry may be configured to supply power to the actuator. In some embodiments in which the aerosol generator comprises a transducer, the control circuitry may be configured to supply power to the transducer. In some embodiments where the aerosol generator comprises a liquid supply element, the control circuitry may be configured to supply power to the liquid supply element. The control circuitry may be configured to supply power to a pump comprised in the liquid supply element. The control circuitry may be configured to synchronise two or more components of the aerosol-generating system. In some embodiments, the control circuitry is configured to synchronise the aerosol-generating element and the liquid supply element.

The control circuitry may be configured to supply power to the aerosol generator continuously following activation of the device or may be configured to supply power intermittently, such as on a puff-by-puff basis. The power may be supplied to the aerosol generator in the form of pulses of electrical current, for example, by means of pulse width modulation (PWM).

Where the aerosol-generator comprises a mesh oscillated by an actuator, the control circuitry may be configured to operate the actuator to oscillate the vibratable element at a predetermined frequency. The predetermined frequency may be between about 20 kHz and about 1500 kHz, or between about 50 kHz and about 1000 kHz, or between about 100 kHz and about 500 kHz. This may provide a desired aerosol-output rate and a desired droplet size for a good user experience.

Where the aerosol generator comprises an oscillating chamber, the control circuitry may be configured to operate the actuator to excite vibrations in the vibratable element at a predetermined frequency. The predetermined frequency may be between about 20 kHz and about 1500 kHz, or between about 50 kHz and about 1000 kHz, or between about 100 kHz and about 500 kHz. This may provide a desired aerosol-output rate and a desired droplet size for a good user experience.

Where the aerosol generator comprises a surface acoustic wave atomiser (SAW-atomiser), the control circuitry may be configured to operate the SAW-atomizer to generate surface acoustic waves at a predetermined frequency. The predetermined frequency may be about 20 MHz or higher, may for example be between about 20 MHz and about 100 MHz, or between about 20 MHz and about 80 MHz. This may provide a desired aerosol output rate and a desired droplet size for a good user experience.

Where the aerosol-generating element is a susceptor element, the aerosol-generating device may comprise an inductive heating assembly. The inductive heating assembly may comprise at least one inductor coil. In these embodiments, the power supply may be coupled to the at least one inductor coil for supplying power to the at least one inductor coil. The at least one inductor coil may be coupled to the control circuitry. The control circuitry may be configured to supply an alternating current to the at least one inductor coil to generate an alternating magnetic field. The susceptor element may be arranged to be penetrated by the alternating magnetic field from the at least one inductor coil, such that the susceptor element is heated by the alternating magnetic field. The control circuitry may be configured to supply power to the inductor coil continuously following activation of the device or may be configured to supply power intermittently, such as on a puff-by-puff basis. The power may be supplied to the inductor coil in the form of pulses of electrical current, for example, by means of pulse width modulation (PWM).

The control circuitry may comprise DC/AC inverter, which may comprise a Class-D or Class-E power amplifier. The control circuitry may comprise further electronic components. For example, in some embodiments, the control circuitry may comprise any of: sensors, switches, display elements.

The aerosol-generating system may comprise an aerosol-generating device and a cartridge configured to couple with the aerosol-generating device. The cartridge may comprise the aerosol generator. The cartridge may further comprise a reservoir for holding liquid aerosol-forming substrate. The cartridge may further comprise a liquid supply element. The aerosol-generating device may comprise the power supply and the control circuitry.

The aerosol-generating device may comprise a housing. The housing may be elongate. The housing may comprise any suitable material or combination of materials. Examples of suitable materials include metals, alloys, plastics or composite materials containing one or more of those materials, or thermoplastics that are suitable for food or pharmaceutical applications, for example polypropylene, polyetheretherketone (PEEK) and polyethylene. The material is preferably light and non-brittle.

The aerosol-generating device housing may define a cavity for receiving a cartridge. The aerosol-generating device may comprise one or more air inlets. The one or more air inlets may enable ambient air to be drawn into the cavity.

The aerosol-generating device may have a connection end configured to couple the aerosol-generating device to a cartridge. The connection end may comprise a cavity for receiving the cartridge.

The aerosol-generating device may have a distal end, opposite the connection end. The distal end may comprise an electrical connector configured to connect the aerosol-generating device to an electrical connector of an external power supply, for charging the power supply of the aerosol-generating device.

According to the present disclosure, there is provided a cartridge for an aerosol-generating system. The cartridge may comprise an aerosol generator as described herein. The cartridge may further comprise a reservoir for holding a liquid aerosol-forming substrate. The cartridge may be disposable. The cartridge may further comprise a liquid supply element configured to supply liquid from the reservoir to the aerosol-generating element.

In some embodiments, the aerosol generator is integrally formed with the cartridge. In other embodiments, the aerosol generator is separate from the cartridge and arranged in the cartridge.

The cartridge may comprise a housing. The housing may be formed from a durable material. The housing may be formed from a liquid impermeable material. The housing may be formed form a mouldable plastics material, such as polypropylene (PP) or polyethylene terephthalate (PET).

The aerosol generator may be arranged in the housing. The aerosol generator may be coupled to the housing. In some embodiments, the housing of the cartridge may form one or more walls of the aerosol generator. The at least one air inlet of the aerosol generator may extend through the housing of the cartridge. The at least one air outlet may extend through the housing of the cartridge.

The housing may define a portion of the reservoir. The housing may define the reservoir. The housing and the reservoir may be integrally formed. Alternatively, the reservoir may be formed separately from the outer housing and arranged in the outer housing.

The cartridge may have a mouth end through which generated aerosol can be drawn by a user. The cartridge may have a connection end configured to connect the cartridge to an aerosol-generating device.

Where the aerosol generator comprises a substantially planar aerosol-generating element, a first side of the aerosol-generating element may face the mouth end of the cartridge and a second side of the aerosol-generating element may face the connection end. In some embodiments, the planar aerosol-generating element extends in a plane that is substantially parallel to a longitudinal axis of the cartridge, extending between the mouth end and the connection end. Where the planar aerosol-generating element extends in a plane that is substantially parallel to a longitudinal axis of the cartridge, the first and second sides of the aerosol-generating element face opposite sides of the cartridge, rather than the mouth end and the connection end of the cartridge.

The cartridge may define the at least one air inlet of the aerosol generator. The at least one air inlet may be arranged at or around the connection end of the cartridge. The cartridge may define a mouth end opening. The at least one air outlet of the aerosol generator may be the mouth end opening of the cartridge. A user may be able to draw aerosol generated from the cartridge through the mouth end opening. The cartridge may define an enclosed airflow passage from the air inlet of the aerosol generator to the mouth end opening. The enclosed airflow passage may extend from the air inlet, past the aerosol-generating element, to the mouth end opening.

The enclosed airflow passage may pass through the reservoir. For example, the reservoir may have an annular cross-section defining an internal passage and the airflow passage may extend through the internal passage of the reservoir.

It will be appreciated that any features described herein in relation to one embodiment of an aerosol generator, an aerosol-generating system, an aerosol-generating device or a cartridge also be applicable to other embodiments of aerosol generators, aerosol-generating systems, aerosol-generating devices or cartridges according to this disclosure. A feature described in relation to one embodiment may be equally applicable to another embodiment in accordance with this disclosure.

It will also be appreciated that an aerosol generator according to this disclosure may be provided in an aerosol-generating device without a cartridge. Accordingly, any of the features described herein with relation to a cartridge may be equally applicable to an aerosol-generating device.

The invention is defined in the claims. However, below there is provided a non-exhaustive list of non-limiting examples. Any one or more of the features of these examples may be combined with any one or more features of another example, embodiment, or aspect described herein.

EX1. An aerosol generator configured to generate an aerosol from an aerosol-forming substrate, the aerosol generator comprising:
an aerosol-generating element configured to aerosolised an aerosol-forming substrate;
at least one air inlet;
at least one air outlet;
a chamber between the air inlet and the at least one air outlet, the aerosol-generating element being arranged in the chamber and configured to release aerosolised aerosol-forming substrate into the chamber; and
an airflow path extending through the chamber between the air inlet and the at least one air outlet, via the aerosol-generating element.

EX2. An aerosol generator
according to example EX1, wherein the at least one air inlet is configured to direct air around a periphery of the chamber.

EX3. An aerosol-generator according to examples EX1 or EX2, wherein the at least one air inlet is arranged to direct air tangentially into the chamber.

EX4. An aerosol generator according to any one of examples EX1, EX2 or EX3, wherein
the chamber extends along a central longitudinal axis.

EX5. An aerosol generator according to example EX4, wherein the chamber is substantially symmetrical about the central longitudinal axis.

EX6. An aerosol generator according to examples EX4 or EX5, wherein the at least one air inlet is configured to direct air into the chamber in a direction that does not intersect with the central longitudinal axis of the chamber.

EX7. An aerosol generator according to any one of examples EX4, EX5 or EX6, wherein the at least one air inlet is configured to direct air into the chamber in a direction around the central longitudinal axis of the chamber.

EX8. An aerosol generator according to example EX1, wherein the aerosol generator comprises a side wall circumscribing the aerosol-generating element and having a surface defining a surface of the chamber.

EX9. An aerosol generator according to example EX8, wherein the at least one air inlet extends through the side wall.

EX10. An aerosol generator according to examples EX8 or EX9, wherein the surface of the side wall is a curved surface and defines a curved surface of the chamber.

EX11. An aerosol generator according to example EX10, wherein the at least one air inlet is configured to direct air into the chamber in a direction tangential to the curved surface of the chamber.

EX12. An aerosol generator according to example EX10, wherein the at least one air inlet is configured to direct air into the chamber in a direction angled from a tangent to the curved surface at an angle of between:
0 degrees and 80 degrees; or
0 degrees and 70 degrees; or
0 degrees and 60 degrees; or
0 degrees and 50 degrees; or
0 degrees and 40 degrees; or
0 degrees and 30 degrees; or
0 degrees and 20 degrees; or
0 degrees and 10 degrees.

EX13. An aerosol generator according to any one of examples EX8 to EX12, wherein the chamber extends along a central longitudinal axis, and wherein the at least one air inlet and the surface of the chamber are configured to direct air around the central longitudinal axis of the chamber.

EX14. An aerosol generator according to any one of examples EX8 to EX13, wherein the surface of the side wall defines a tapered chamber.

EX15. An aerosol generator according to example EX8 to EX14, wherein the chamber comprises a mouth end and an aerosol-generation end opposite the mouth end, wherein the at least one air outlet is arranged at a mouth end, and wherein a width of the chamber at the mouth end is less than a width of the chamber at the aerosol-generation end.

EX16. An aerosol generator according to example EX15, wherein the aerosol-generating element is arranged at the aerosol-generation end of the chamber.

EX17. An aerosol generator according to any one of examples EX8 to EX16, wherein the side wall defines a circularly conical surface of the chamber.

EX18. An aerosol-generator according to any one of examples EX8 to EX16, wherein the side wall defines an elliptically conical surface of the chamber.

EX19. An aerosol generator according to any one of examples EX8 to EX13, wherein the surface of the side wall defines a circularly cylindrical surface of the chamber.

EX20. An aerosol generator according to any one of examples EX8 to EX13, wherein the surface of the side wall defines an elliptically cylindrical surface of the chamber.

EX21. An aerosol generator according to any one of examples EX1 to EX20, wherein the aerosol-generating element is a non-thermal aerosol-generating element.

EX22. An aerosol generator according to example EX21, wherein the non-thermal aerosol-generating element comprises a mesh element having a plurality of nozzles.

EX23. An aerosol-generator according to example EX22, wherein the mesh aerosol-generating element is configured to aerosolised aerosol-forming substrate when aerosol-forming substrate passes through the nozzles when the vibratable mesh element is oscillated.

EX24. An aerosol-generator according to example EX23, further comprises an actuator coupled to the mesh and configured to oscillate the mesh aerosol-generating element.

EX25. An aerosol generator according to example EX22, wherein the aerosol generator comprises an oscillation chamber having:
a cavity containing a liquid to be aerosolised;
a liquid inlet for providing a supply of the liquid to be atomized to the cavity;
an elastically deformable element;
the mesh aerosol-generating element; and
an actuator arranged to oscillate the elastically deformable element, and
wherein oscillation of the elastically deformable element by the actuator varies the pressure inside the cavity to eject liquid contained in the cavity from the cavity through the nozzles of the mesh aerosol-generating element.

EX26. An aerosol generator according to examples EX24 or EX25, wherein the actuator is a piezoelectric transducer.

EX27. An aerosol generator according to example EX21, wherein the aerosol-generating element is part of a surface acoustic wave atomizer (SAW-atomiser).

EX28. An aerosol generator according to example EX27, wherein the SAW-atomizer comprises:
a substrate comprising an active surface; and
at least one transducer positioned on the active surface of the substrate for generating surface acoustic waves on the active surface of the substrate,
wherein the aerosol-generating element forms the substrate.

EX29. An aerosol generator according to any one of examples EX1 to EX28, wherein the at least one air inlet is configured to direct air into the chamber in a direction away from the aerosol-generating element.

EX30. An aerosol generator according to any one of examples EX1 to EX29, wherein the at least one air inlet is configured to direct air into the chamber in a direction that does not intersect with the aerosol-generating element.

EX31. An aerosol generator according to any one of examples EX1 to EX30, wherein the at least one air inlet is configured to direct air into the chamber in a direction at least partially towards the at least one air outlet.

EX32. An aerosol generator according to any one of examples EX1 to EX31, wherein the chamber comprises a mouth end and an aerosol-generation end opposite the mouth end, wherein the at least one air outlet is arranged at a mouth end, and wherein the aerosol-generating element is arranged at the aerosol-generation end.

EX33. An aerosol generator according to example EX32, wherein the at least one air inlet is arranged towards the aerosol-generation end of the chamber.

EX34. An aerosol generator according to examples EX32 or EX33, further comprising a side wall that circumscribes the aerosol-generating element and extends between the aerosol-generating element at the aerosol-generation end, and the at least one air outlet at the mouth end.

EX35. An aerosol generator according to example EX34, wherein the at least one air inlet extends through the side wall.

EX36. An aerosol generator according to any one of examples EX32 to EX35, wherein the at least one air inlet is configured to direct air into the chamber in a direction towards the mouth end of the chamber.

EX37. An aerosol generator according to any one of examples EX1 to EX36, wherein the aerosol-generating element defines at least a portion of a surface of the chamber.

EX38. An aerosol generator according to any one of examples EX1 to EX37, wherein the chamber extends along a central longitudinal axis, and wherein the at least one air inlet is arranged to direct air into the chamber in a direction that is not perpendicular to the central longitudinal axis.

EX39. An aerosol generator according to any one of examples EX1 to EX37, wherein the chamber extends along a central longitudinal axis, and wherein the at least one air inlet is arranged to direct air into the chamber in a direction that is angled from the central longitudinal axis at an angle of between:
1 degree and 89 degrees; or
5 degrees and 85 degrees; or
10 degrees and 80 degrees; or
15 degrees and 75 degrees; or
20 degrees and 70 degrees; or
25 degrees and 65 degrees; or
30 degrees and 60 degrees.

EX40. An aerosol generator according to any one of examples EX1 to EX39, wherein the aerosol-generating element is a planar aerosol-generating element.

EX41. An aerosol generator according to example EX40, wherein the planar aerosol-generating element extends substantially in a plane.

EX42. An aerosol generator according to example EX41, wherein the chamber extends along a central longitudinal axis, and wherein the plane of the planar aerosol-generating element is perpendicular to the central longitudinal axis of the chamber.

EX43. An aerosol generator according to examples EX41 or EX42, wherein the at least one air inlet is arranged to direct air into the chamber in a direction away from the plane of the planar aerosol-generating element.

EX44. An aerosol-generator according to any one of examples EX41 to EX43, wherein the at least one air inlet is arranged to direct air in a direction between the plane of the planar aerosol-generating element and the at least one air outlet.

EX45. An aerosol-generator according to any one of examples EX41 to EX44, wherein the at least one air inlet is arranged to direct air in a direction angled from the plane of the planar aerosol-generating element at an angle of between:
1 degree and 89 degrees; or
5 degrees and 85 degrees; or
10 degrees and 80 degrees; or
15 degrees and 75 degrees; or
20 degrees and 70 degrees; or
25 degrees and 65 degrees; or
30 degrees and 60 degrees; or
65 degrees and 85 degrees; or
70 degrees and 80 degrees.

EX46. An aerosol-generator according to examples EX41 or EX42, wherein the at least one air inlet is arranged to direct air in a direction parallel to the plane of the planar aerosol-generating element.

EX47. An aerosol-generator according to any one of examples EX1 to EX46, wherein the at least one air inlet has one of:
a circular cross-section;
an elliptical cross-section;
a square cross-section;
a rectangular cross-section; or
a triangular cross-section.

EX48. An aerosol generator according to any one of examples EX1 to EX47, wherein the at least one air inlet has a polygonal cross-section.

EX49. An aerosol generator according to any one of examples EX1 to EX48, wherein the at least one air inlet has a total cross-sectional area of between:

2 square millimetres and 30 square millimetres; or
2 square millimetres and 25 square millimetres; or
5 square millimetres and 20 square millimetres; or
5 square millimetres and 20 square millimetres; or
5 square millimetres and 15 square millimetres.

EX50. An aerosol generator according to any one of examples EX1 to EX49, wherein the at least one air inlet comprises two air inlets, a first air inlet and a second air inlet.

EX51. An aerosol generator according to example EX50, wherein the first air inlet is configured to direct air in the chamber in a first direction, and wherein the second air inlet is configured to direct air in the chamber in a second direction, different to the first direction.

EX52. An aerosol generator according to examples EX50 or EX51, wherein the first air inlet is configured to direct air in the chamber in a first direction, and wherein the second air inlet is configured to direct air in the chamber in a second direction, opposite to the first direction.

EX53. An aerosol generator according to any one of examples EX50 to EX52, wherein the first air inlet is arranged at a first side of the chamber, and the second air inlet is arranged at a second side of the chamber, opposite the first air inlet.

EX54. An aerosol generator according to any one of examples EX50 to EX53, wherein the chamber extends along a central longitudinal axis, and wherein the first air inlet and the second air inlet are located at the same position along the longitudinal axis.

EX55. An aerosol generator according to any one of examples EX50 to EX53, wherein the chamber extends along a central longitudinal axis, and wherein the first air inlet is arranged at a first position along the longitudinal axis, and the second air inlet is arranged at a second positon along the longitudinal axis, different to the first position.

EX56. An aerosol generator according to any one of examples EX1 to EX49, wherein the at least one air inlet comprises a plurality of air inlets.

EX57. An aerosol generator according to example 56, wherein the plurality of air inlets are spaced around the circumference of the aerosol-generating element.

EX58. An aerosol generator according to examples EX56 or EX57, wherein the chamber extends along a central longitudinal axis, and wherein the plurality of air inlets are located at different positions along the central longitudinal axis of the chamber

EX59. An aerosol generator according to examples EX56 or EX57, wherein the chamber extends along a central longitudinal axis, and wherein the plurality of air inlets are located at the same position along the central longitudinal axis of the chamber

EX60. An aerosol generator according to any one of examples 50 to 59, wherein all of the air inlets have the same cross-sectional shape.

EX61. An aerosol generator according to any one of examples 50 to 60, wherein the air inlets have the same cross-sectional area.

EX62. An aerosol generator according to any one of examples 50 to 59, wherein the air inlets have different cross-sectional shapes.

EX63. An aerosol generator according to any one of examples 50 to 59, wherein the air inlets have different cross-sectional areas.

EX64. An aerosol generator according to any one of examples EX1 to EX63, wherein the combined total cross-sectional area of the air inlets is between:
2 square millimetres and 30 square millimetres; or
2 square millimetres and 25 square millimetres; or
5 square millimetres and 20 square millimetres; or
5 square millimetres and 20 square millimetres; or
5 square millimetres and 15 square millimetres.

EX65. An aerosol generator according to any one of examples EX1 to EX64, wherein the at least one air inlet is formed by an air passage.

EX66. An aerosol generator according to example EX65, wherein the air passage forming the at least one air inlet extends between an external surface of the aerosol generator and a surface defining the chamber.

EX67. An aerosol generator according to examples EX65 or EX66, wherein the air passage forming the at least one air inlet has a length and a cross-section at the surface defining the chamber, and wherein the length of the air passage is greater than the dimensions of the cross-section of the air inlet at the surface of the chamber.

EX68. An aerosol-generating system comprising:
a reservoir for holding a liquid aerosol-forming substrate;
an aerosol generator according to any one of examples EX1 to EX67; and
a liquid supply element configured to supply liquid from the reservoir to the aerosol-generating element.

EX69. An aerosol-generating system according to example EX68, further comprising:
a power supply coupled to the aerosol generator for supplying power to the aerosol generator; and
control circuitry configured to control the supply of power from the power supply to the aerosol generator.

EX70. An aerosol-generating system according to example EX69, further comprising:
a cartridge comprising the reservoir, the aerosol generator, and the liquid supply element; and
a device configured to receive the cartridge, the device comprising the power supply and the control circuitry.

EX71. A cartridge for an aerosol-generating system, the cartridge comprising:
a reservoir for holding a liquid aerosol-forming substrate;
an aerosol generator according to any one of examples EX1 to EX67; and
a liquid supply element configured to supply liquid from the reservoir to the aerosol-generating element.

EX72. An aerosol generator configured to generate an aerosol from an aerosol-forming substrate, the aerosol generator comprising:

a planar aerosol-generating element configured to aerosolise an aerosol-forming substrate;
a planar ancillary element coupled to the aerosol-generating element; and
at least one air inlet extending through the planar ancillary element,
wherein the planar aerosol-generating element and the planar ancillary element extend substantially in the same plane, and wherein the at least one air inlet is configured to direct air in a direction away from the plane.

EX73. An aerosol generator according to example EX72, wherein the planar ancillary element circumscribes the planar aerosol-generating element.

EX74. An aerosol generator according to examples EX72 or EX73, wherein the aerosol-generating element comprises a mesh element having a plurality of nozzles.

EX75. An aerosol generator according to example EX74, wherein the planar ancillary element comprises a planar actuator element configured to oscillate the mesh aerosol-generating element.

EX76. An aerosol generator according to example EX74, wherein the planar ancillary element comprises a planar support element, and a planar actuator element, wherein the planar actuator element is coupled to the mesh aerosol-generating element and is configured to oscillate the mesh aerosol-generating element.

EX77. An aerosol generator according to example EX76, wherein the at least one air inlet extends through the planar support element.

EX78. An aerosol-generator according to examples EX76 or EX77, wherein the planar actuator element circumscribes the mesh aerosol-generating element, and the planar support element circumscribes the planar actuator element.

EX79. An aerosol generator according to any one of examples EX75 to EX78, wherein the at least one air inlet extends through the planar actuator element.

EX80. An aerosol generator according to any one of examples EX75 to EX79, wherein the planar actuator element comprises a piezoelectric transducer.

EX81. An aerosol generator according to any one of examples EX72 to EX80, wherein the at least one air inlet forms a slot through the planar ancillary element.

EX82. An aerosol generator according to any one of examples EX72 to EX81, wherein the at least one air inlet has one of a circular, elliptical, square, rectangular or triangular cross-section.

EX83. An aerosol generator according to any one of examples EX72 to EX81, wherein the at least one air inlet has a polygonal cross-section.

EX84. An aerosol generator according to any one of examples EX72 to EX83, wherein the at least one air inlet is configured to direct air in a direction perpendicular to the plane.

EX85. An aerosol generator according to any one of examples EX72 to EX83, wherein the at least one air inlet is configured to direct air in a direction between the plane and a direction perpendicular to the plane.

EX86. An aerosol generator according to any one of examples EX72 to EX83, wherein the at least one air inlet is configured to direct air in a direction angled to the plane at an angle of between:
1 degree and 89 degrees; or
5 degrees and 85 degrees; or
10 degrees and 80 degrees; or
15 degrees and 75 degrees; or
20 degrees and 70 degrees; or
25 degrees and 65 degrees; or
30 degrees and 60 degrees; or
65 degrees and 85 degrees; or
70 degrees and 80 degrees.

EX87. An aerosol generator according to any one of examples EX72 to EX836 wherein the at least one air inlet comprises a plurality of air inlets.

EX88. An aerosol generator according to example EX87, wherein the plurality of air inlets are spaced around the circumference of the ancillary element.

EX89. An aerosol generator according to any one of examples EX87 to EX88, wherein the plurality of air inlets have different cross-sectional shapes.

EX90. An aerosol generator according to any one of examples EX87 to EX89, wherein the plurality of air inlets have different cross-sectional areas.

EX91. An aerosol generator according to examples EX87 or EX88, wherein the plurality of air inlets have identical cross-sections.

EX92. An aerosol-generating system comprising:
a reservoir for holding a liquid aerosol-forming substrate;
an aerosol generator according to any one of examples EX72 to EX91; and
a liquid supply element configured to supply liquid from the reservoir to the aerosol-generating element.

EX93. An aerosol-generating system according to example EX92, further comprising:
a power supply coupled to the aerosol generator for supplying power to the aerosol generator; and
control circuitry configured to control the supply of power from the power supply to the aerosol generator.

EX94. An aerosol-generating system according to example EX93, further comprising:
a cartridge comprising the reservoir, the aerosol generator, and the liquid supply element; and
a device configured to receive the cartridge, the device comprising the power supply and the control circuitry.

EX95. A cartridge for an aerosol-generating system, the cartridge comprising:
a reservoir for holding a liquid aerosol-forming substrate;
an aerosol generator according to any one of examples EX72 to EX91; and
a liquid supply element configured to supply liquid from the reservoir to the aerosol-generating element.

Examples will now be further described with reference to the figures in which:

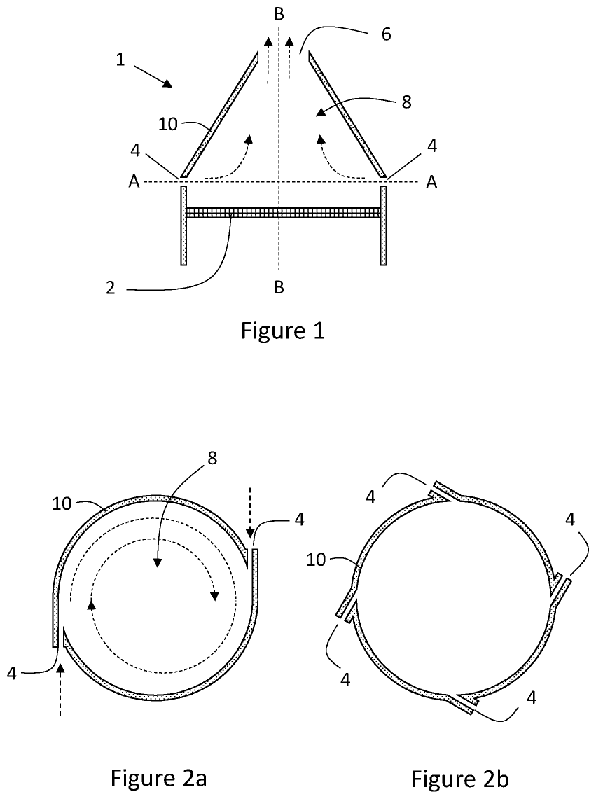

FIG. 1 shows a schematic illustration of an aerosol generator according to an embodiment of this disclosure;

FIG. 2a shows a cross-section along line A-A through the chamber of the aerosol generator of FIG. 1;

FIG. 2b shows a cross-section along line A-A through the chamber of an aerosol generator according to another embodiment of the disclosure;

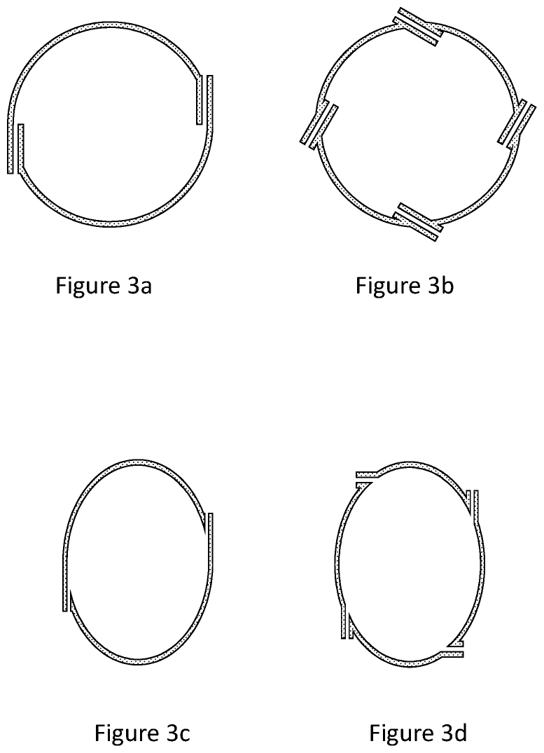

FIGS. 3a-3d show cross-sections along line A-A through the chambers of an aerosol generators according to other embodiments according of this disclosure;

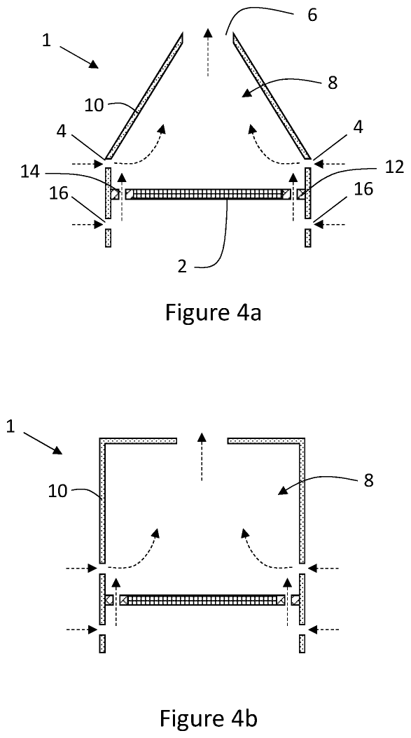

FIG. 4a shows a schematic illustration of an aerosol generator according to another embodiment of this disclosure;

FIG. 4b shows a schematic illustration of an aerosol generator according to another embodiment of this disclosure;

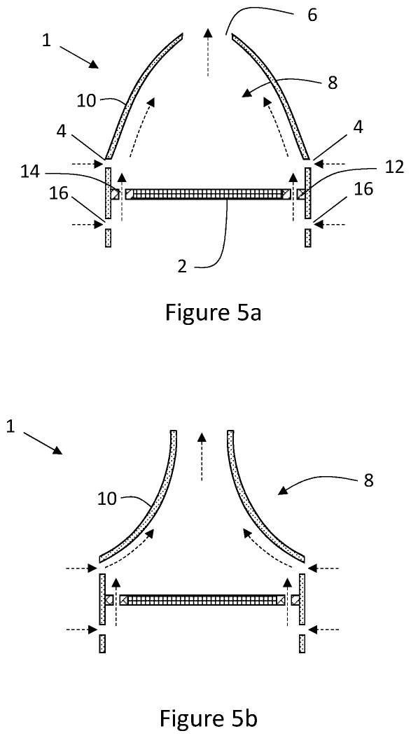

FIG. 5a shows a schematic illustration of an aerosol generator according to another embodiment of this disclosure;

FIG. 5b shows a schematic illustration of an aerosol generator according to another embodiment of this disclosure;

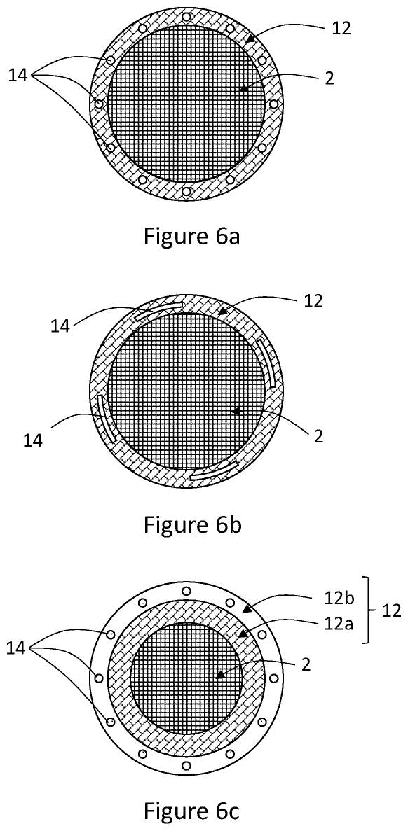

FIGS. 6a-6c show plan views of aerosol-generating elements coupled with ancillary elements according to embodiments of this disclosure;

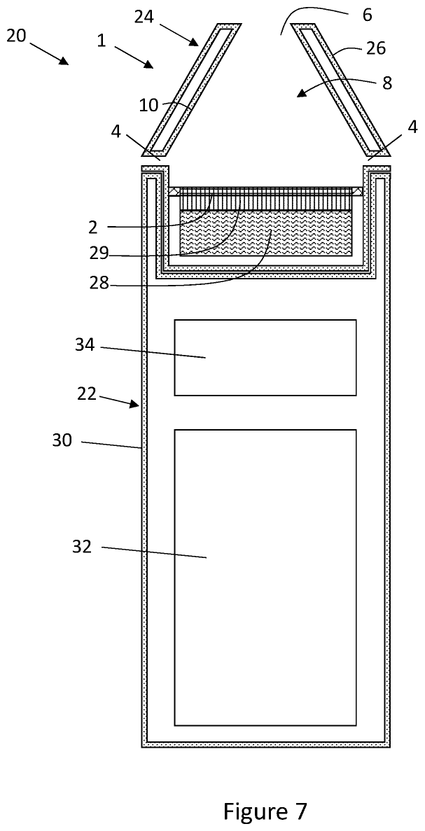

FIG. 7 shows a schematic illustration of an aerosol-generating system according to an embodiment of this disclosure, the aerosol-generating system comprising a cartridge having the aerosol-generator of FIG. 1, and an aerosol-generating device coupled with the cartridge;

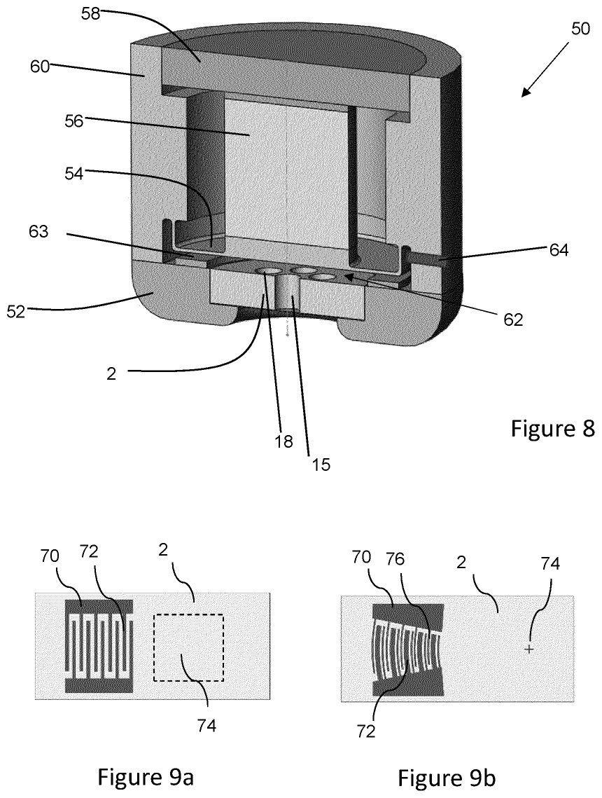

FIG. 8 shows an oscillation chamber comprising an aerosol-generating element according to an embodiment of this disclosure;

FIGS. 9a-9b show schematic illustrations of embodiments of surface acoustic wave atomisers (SAW-atomisers) according to an embodiment of this disclosure;

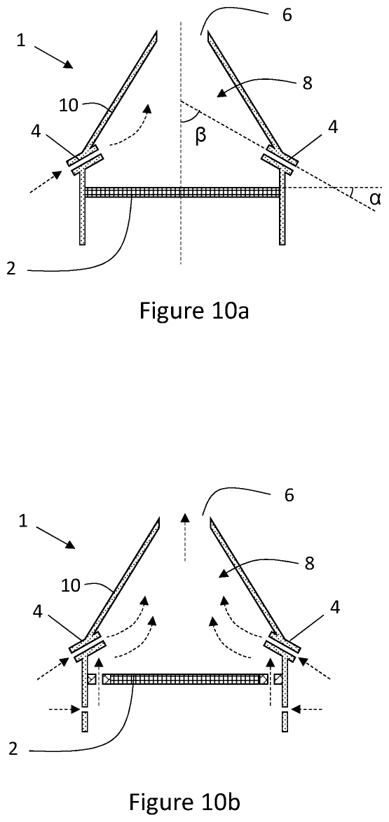

FIG. 10a shows a schematic illustration of an aerosol generator according to another embodiment of this disclosure; and

FIG. 10b shows a schematic illustration of an aerosol generator according to another embodiment of this disclosure.

FIG. 1 shows a schematic illustration of an aerosol generator 1 according to an embodiment of the present disclosure.

The aerosol generator 1 comprises a non-thermal aerosol-generating element 2 configured to aerosolise an aerosol-forming substrate by means other than heating. In this embodiment, the aerosol-generating element 2 is a mesh element having passages through which liquid aerosol-forming substrate may pass and be aerosolised when the mesh element is oscillated. An actuator (not shown), in the form of a piezoelectric transducer is coupled to the mesh aerosol-generating element and is configured to oscillate the aerosol-generating element to aerosolise liquid aerosol-forming substrate in contact with the aerosol-generating element.

The aerosol generator 1 further comprises a pair of air inlets 4, arranged at opposite sides of the aerosol generator, and an air outlet 6. A chamber 8 is formed between the pair of air inlets 4 and the air outlet 6. The aerosol-generating element 2 is arranged in the chamber 8 and configured to release aerosolised aerosol-forming substrate into the chamber 8. An airflow path extends through the chamber between the air inlets 4 and the at least one air outlet 6, via the aerosol-generating element 2. The airflow path is denoted by the dashed arrows shown in FIG. 1.

The chamber 8 has a mouth end and an aerosol-generation end, opposite the mouth end. The air outlet 6 is arranged at the mouth end of the chamber 8. The aerosol-generating element 2 is arranged at the aerosol-generation end of the chamber 8. A major surface of the aerosol-generating element defines the aerosol-generation end of the chamber 8. A side wall 10 circumscribes the aerosol-generating element 2, and an inner surface of the side wall 10 defines the sides of the chamber 8, between the mouth end and the aerosol-generation end. The air inlets 4 extend through the side wall 10 and are located towards the aerosol-generation end, in close proximity to the aerosol-generation element 2.

The side wall 10 has a curved inner surface, which defines a curved surface of the chamber 8. In this embodiment, the inner surface of the side wall 10 defines a substantially circular cross-sectional shape, providing the cavity 8 with a substantially circular cross-sectional shape along its length, as shown in FIG. 2a, which is a cross-sectional view through the aerosol generator 1 along line A-A. The side wall 10 also tapers from the aerosol-generation end to the mouth end, such that the inner surface of the side wall 10 defines a substantially circularly conical chamber 8. The chamber 8 extends along a central longitudinal axis and is substantially rotationally symmetrical about the central longitudinal axis, which is shown in FIG. 1a by dashed line B-B.

The aerosol-generating element 2 is a planar element, extending substantially in a plane. In this embodiment, the plane of the aerosol-generating element 2 is substantially perpendicular to the central longitudinal axis of the chamber 8. The aerosol-generating element 2 is centred on the central longitudinal axis of the chamber 8, and a major surface of the aerosol-generating element 2 faces the air outlet 6. The aerosol-generating element 2 is thin, having a thickness that this substantially smaller than its diameter, and has a generally circular shape.

As shown in FIG. 2a, the air inlets 4 are positioned to direct air into the chamber 8 from opposite sides of the chamber 8. Each of the air inlets 4 extends through the side wall 10 in a direction tangential to the curved inner surface of the side wall 10. As such, the air inlets 4 are oriented to direct air into the chamber 8 at a tangent to the curved inner surface of the side wall 10. In other words, the air inlets 4 direct air into the chamber along the curved inner surface of the side wall 10. The orientation of the air inlets 4 and the curved surface of the side wall 10 cause air entering the chamber 8 through the air inlets 4 to swirl along the periphery of the chamber 8, as shown by the dashed arrow in FIG. 2a. The swirling air along the periphery of the chamber directs aerosolised aerosol-forming substrate from the aerosol-generating element 2 away from the side wall 10, which reduces deposition of the aerosolised aerosol-forming substrate on the side wall 10 and increases the proportion of aerosolised aerosol-forming substrate that exits the chamber via the air outlet 6 at the mouth end of the chamber 8.

FIG. 2b shows a cross-sectional view through an aerosol generator according to another embodiment of the disclosure. The aerosol generator of FIG. 2b is similar to the aerosol generator 1 of FIGS. 1 and 2a, and like reference numerals are used to denote like features. The aerosol generator shown in FIG. 2b differs from the aerosol generator 1 of FIGS. 1 and 2a, in that the aerosol generator has four air inlets 4, spaced equally around the circumference of the side wall 10.

FIGS. 3a-d show cross-sectional views through aerosol generators according other embodiments of the disclosure.

FIGS. 3a and 3b show aerosol generators that are substantially similar to the aerosol generators shown in FIGS. 2a and 2b respectively. The aerosol generators shown in FIGS. 3a and 3b differ from the aerosol generators shown in FIGS. 2a and 2b in that the air inlets extend into the chamber 8. The air inlets of the aerosol generators shown in FIGS. 3a and 3b comprise air passages, having a length. Increasing the length of the air passages improves the directionality of the air entering the chamber.

FIGS. 3c and 3d show aerosol generators that are substantially similar to the aerosol generators shown in FIGS. 2a and 2b respectively. The aerosol generators shown in FIGS. 3c and 3d differ from the aerosol generators shown in FIGS. 2a and 2b in that the inner surface of the side wall 10 defines a substantially elliptical cross-sectional shape, providing the cavity 8 with a substantially elliptical cross-sectional shape along its length. In these embodiments, the inner surface of the side wall 10 defines a substantially elliptically conical chamber 8.

FIGS. 4a and 4b show schematic illustrations of aerosol generators 1 according to other embodiments of the present disclosure. The aerosol generators of FIGS. 4a and 4b are similar to the aerosol generator 1 of FIGS. 1 and 2a, and like reference numerals are used to denote like features.

The aerosol generator 1 shown in FIG. 4a differs from the aerosol generator 1 shown in FIGS. 1 and 2a in that the aerosol-generating element 2 is circumscribed by an ancillary element 12. A plurality of air inlets 14 extend through the ancillary element 12 and are spaced evenly around the circumference of the ancillary element 12. In this embodiment, the ancillary element 12 is a support element that couples the aerosol-generating element 2 to the side wall 10 of the aerosol generator 1. The plurality of air inlets 14 extending through the ancillary element 12 are configured to direct air into the chamber 8 away from the plane of the aerosol-generating element 2. In this embodiment, the plurality of air inlets 14 are oriented to direct air into the chamber 8 in a direction substantially parallel with the central longitudinal axis of the chamber, towards the mouth end of the chamber and the air outlet 6. The side wall 10 also comprises additional air inlets 16, below the aerosol-generating element 2, to enable ambient air to be drawn into the aerosol generator 1 through the side wall and subsequently into the chamber 8 through the air inlets 14 in the ancillary element 12.

The aerosol generator 1 shown in FIG. 4b is substantially the same as the aerosol generator 1 shown in FIG. 4a, apart from the side wall 10 of the aerosol generator 1 shown in FIG. 4b does not taper, and maintains a consistent diameter along the length of the aerosol generator. Accordingly, the inner surface of the side wall 10 of the aerosol generator 1 shown in FIG. 4b defines a circularly cylindrical chamber 8.

FIGS. 5a and 5b show schematic illustrations of aerosol generators 1 according to other embodiments of the present disclosure. The aerosol generators of FIGS. 5a and 5b are similar to the aerosol generator 1 of FIG. 4a, and like reference numerals are used to denote like features.

The aerosol generator 1 shown in FIG. 5a differs from the aerosol generator 1 shown in FIG. 4a in that the chamber 8 is tapered inwards at an increasing rate or angle from the aerosol-generation end to the mouth end, such that the inner surface of the side wall 10 defines a substantially domed chamber 8, which is narrower at the mouth end than the aerosol-generation end. The increasing taper angle of the side wall 10 relative to the central longitudinal axis of the chamber 8 results in the inner surface of the side wall 10 defining a concave surface of the domed chamber 8.

The aerosol generator 1 shown in FIG. 5b differs from the aerosol generator 1 shown in FIG. 4a in that the chamber 8 is tapered inwards at a decreasing rate or angle from the aerosol-generation end to the mouth end, such that the inner surface of the side wall 10 defines a substantially horn shaped chamber 8, which is narrower at the mouth end than the aerosol-generation end. The decreasing taper angle of the side wall 10 relative to the central longitudinal axis of the chamber 8 results in the inner surface of the side wall 10 defining a convex surface of the horn shaped chamber 8.

FIGS. 6a-6c show plan view of aerosol-generating elements 2 coupled with ancillary elements 12, according to embodiments of the disclosure. In each of these embodiments, the aerosol-generating elements 2 are planar mesh elements that are configured to be oscillated to aerosolise liquid aerosol-forming substrate.

FIG. 6a shows a circular, mesh aerosol-generating element 2 circumscribed by an ancillary element 12. The mesh aerosol-generating element 2 and the ancillary element 12 are both planar and extend in the same plane. In this embodiment, the ancillary element 12 is a piezoelectric transducer that is arranged to oscillate the mesh aerosol-generating element 12. The piezoelectric transducer comprises a plurality of air inlets 14 spaced evenly around the circumference of the piezoelectric transducer. The air inlets are have a circular cross-section and are configured to direct air away from the plane of the aerosol-generating element 2 and the ancillary element 12.

FIG. 6b shows a circular, mesh aerosol-generating element 2 circumscribed by an ancillary element 12, substantially similar that shown in FIG. 6a. The ancillary element 12 shown in FIG. 6b differs to that shown in FIG. 6a in that the plurality of air inlets 14 are rectangular slots extending through the ancillary element 12.

Figure c shows a circular, mesh aerosol-generating element 2 circumscribed by an ancillary element 12. The mesh aerosol-generating element 2 and the ancillary element 12 are both planar and extend in the same plane. In this embodiment, the ancillary element 12 comprises a piezoelectric transducer 12a, that is arranged to oscillate the mesh aerosol-generating element 12, and a support element 12b. The piezoelectric transducer 12a is coupled to the aerosol-generating element 2 and circumscribes the aerosol-generating element 2. The support element 12b is coupled to the piezoelectric transducer 12a and circumscribes the piezoelectric transducer 12a. The support element 12b comprises a plurality of air inlets 14 spaced evenly around the circumference of the support element 12b. The air inlets 14 are have a circular cross-section and are configured to direct air away from the plane of the aerosol-generating element 2 and the ancillary element 12.

FIG. 7 shows a schematic illustration of an aerosol-generating system 20 according to the disclosure. The aerosol-generating system 20 comprises an aerosol-generating device 22 and a cartridge 24 coupled to the aerosol-generating device 22.

The cartridge 24 comprises an aerosol generator 1 that is substantially similar to the aerosol generator 1 shown in FIGS. 1 and 2a, and like references are used to denote like features. The cartridge 24 further comprises housing 26, a liquid reservoir 28 holding a liquid aerosol-forming substrate and a liquid supply element 29 fluidly connecting the liquid reservoir 28 to the aerosol generator 1.

The aerosol generator 1 is integrally formed with the housing 26 of the cartridge 24, such that the side wall 10 of the aerosol generator is formed by the housing 26 of the cartridge 24. The air inlets 4 extend through the housing 26 of the cartridge, such that ambient air may be drawn into the chamber through the housing 26 of the cartridge through the air inlets 4. The air outlet 6 at the mouth end of the chamber 8 forms a mouth end opening of the cartridge 24, through which aerosol is delivered to a user. An airflow path is formed between the air inlets 4 and the mouth end opening 6, via the aerosol-generating element 2.

The liquid transfer element 29 is formed from a body of wicking material, having one end received in the reservoir 28 and the other end in contact with the aerosol-generating element 2 of the aerosol-generating element 2. The liquid transfer element 29 is configured to deliver liquid aerosol-forming substrate from the reservoir 28 to the aerosol-generating element 2.

The aerosol-generating element 2 is a planar mesh element that is configured to be oscillated to aerosolise liquid aerosol-forming substrate delivered to the aerosol-generating element 2 from the reservoir 28. An actuator in the form of a piezoelectric transducer (not shown) is coupled to the aerosol-generating element 2 to oscillate the aerosol-generating element. Electrical contacts (not shown) are provided from the actuator to a connection end of the cartridge 24 for the supply of electrical energy to the actuator from the aerosol-generating device 22, when the cartridge 24 is coupled with the aerosol-generating device 22.

The aerosol-generating device 22 comprises a housing 30 forming a cavity at a connection end for coupling the aerosol-generating device 22 to the cartridge 24. The aerosol-generating device further comprises a power supply 32 and control circuitry 34 contained within the housing 30. The power supply 32 is a rechargeable lithium-ion battery. Electrical contacts (not shown) are provided in the cavity of the device 22 for coupling the power supply 32 and control circuitry 34 to the cartridge 24 when the cartridge is received in the cavity. The control circuitry 34 is configured to control the supply of power from the power supply 32 to the cartridge 24.

In use, when the cartridge 24 is received in the cavity of the device 22, the aerosol-generating system 20 may be activated either by a user puffing on the mouth end of the cartridge and a sensor (not shown) in the device 22 detecting the puff, or by a user pressing a button. When the aerosol-generating system is activated, the control circuitry 34 supplies power from the power supply 32 to the actuator of the aerosol generator 1 in the cartridge 22. The actuator oscillates the aerosol-generating element 2, which aerosolises liquid aerosol-forming substrate delivered to the aerosol-generating element 2 from the reservoir 28 by the liquid transfer element 29.

When a user draws on the mouth end of the cartridge 24, ambient air is drawn into the chamber 8 through the air inlets 4, along the airflow path. The ambient air in the chamber 8 is directed along the periphery of the chamber 8 by the air inlets 4 and the curved surface of the side wall 10. Aerosolised aerosol-forming substrate is produced in the chamber 8 by the aerosol-generating element 2 and forms an aerosol that is drawn towards the mouth end opening 6 of the cartridge. The ambient air swirling along the periphery of the chamber directs the generated aerosol away from the surfaces of the chamber 8, inhibiting deposition of the generated aerosol droplets on the surfaces of the cartridge. The aerosol is drawn from the chamber 8 through the mouth end opening and is delivered to the user for inhalation.

FIG. 8 shows a perspective cross-sectional view of a planar, mesh aerosol-generating element 2 forming part of an oscillation chamber 50. Such an oscillation chamber may be arranged at the aerosol-generation end of the chamber 8 of an aerosol generator 1 according to embodiments of the disclosure. Accordingly, FIG. 8 shows an alternative non-thermal aerosol-generating element 2 that may be employed in an aerosol generator according to the disclosure. The mesh element 2 is received within a mesh element housing 52. The oscillation chamber 50 also comprises an elastically deformable element 54 and an actuator 56 arranged to oscillate the elastically deformable element 54. The actuator 56 is a piezoelectric transducer.

The oscillation chamber 50 also comprises a pre-loading element 58 arranged to compress the actuator 56 between the pre-loading element 58 and the elastically deformable element 54. The pre-loading element 58, the actuator 56 and the elastically deformable element 54 are arranged within an actuator housing 60. The actuator housing 60 is attached to the mesh element housing 52 to define a cavity 62 between the mesh element 2 and the elastically deformable element 54. The actuator housing 60 defines a liquid inlet 64 for providing a supply of liquid to be aerosolised to the cavity 62.

The elastically deformable element 54 extends radially outward of the mesh element 2, over the mesh element housing 52 to the actuator housing 60. The region of the cavity 62 between the mesh element 2 and the elastically deformable element 54 is substantially circularly cylindrical. The mesh element housing 52 comprises a raised region 63 about the circumference of the mesh element 2, such that the gap between the mesh element housing 52 and the elastically deformable element 54 is narrowed around the circumference of the mesh element 2. The narrow gap between the raised region 63 of the mesh element housing 52 and the elastically deformable element 54 restricts the flow of liquid into and out of the region of the cavity 62 directly between the mesh element 2 and the elastically deformable element 54, which facilitates the generation of a high pressure of the liquid in this region. The outer region of the cavity 62, radially outward from the raised region 63 of the mesh element housing 52, extends partially into the actuator housing 60, to provide a region of the cavity 62 that is able to hold a small volume of liquid outside of the region directly between the mesh element 2 and the elastically deformable element 54. This outer region of the cavity 62 provides a reserve supply of liquid to the region between the mesh element 2 and the elastically deformable element 54 as liquid is depleted from that region during operation. The liquid inlet 64 is provided in the actuator housing 60 to supply liquid to the outer region of the cavity 62. The liquid inlet 64 is arranged offset from the region of the cavity 62 between the mesh element 2 and the elastically deformable element 54. This arrangement of the liquid inlet may reduce the possibility of liquid being pushed out of the cavity through the liquid inlet when subjected to oscillations from the elastically deformable element. This may also reduce the likelihood of air being drawn directly into that region from the liquid inlet 64.

During use, liquid to be aerosolise is supplied to the cavity 62 through the liquid inlet 64. The actuator 56 oscillates the elastically deformable element 54 to force at least some of the liquid within the cavity 62 through the channels 15 and the nozzles 18 of the mesh element 2. The liquid forced through the nozzles 18 of the mesh element 2 form droplets. The momentum of the liquid forced through the nozzles 18 to form the droplets carries the droplets away from the mesh element 2. Therefore, during use, the oscillation chamber 50 generates an aerosol comprising liquid droplets ejected through the mesh element 2.

FIGS. 9a and 9b show schematic illustrations of surface acoustic wave atomisers (SAW-atomisers). Such SAW-atomisers may be arranged at the aerosol-generation end of the chamber 8 of an aerosol generator 1 according to embodiments of the disclosure. Accordingly, FIGS. 9a and 9b shows alternative non-thermal aerosol-generating elements 2 that may be employed in an aerosol generator according to the disclosure.

FIG. 9a shows a SAW-atomiser having an aerosol-generating element 2 in the form of a piezoelectric substrate with an active surface. In this embodiment, one interdigital transducer 70 is arranged on a lateral surface portion of the piezoelectric substrate 2. The transducer 70 is a straight transducer, comprising a series of straight interlacing electrodes 72 arranged in parallel (straight transducer). An atomization region 74 on the active surface of the piezoelectric substrate 2 is indicated by a dotted line and is located near the transducer 70 but on an opposite lateral surface portion of the piezoelectric substrate 2.

FIG. 9b shows a SAW-atomiser having an aerosol-generating element 2 in the form of a piezoelectric substrate with an active surface. In this embodiment, one interdigital transducer 70 is arranged on a lateral surface portion of the piezoelectric substrate 2. The transducer 70 is a focussing transducer, comprising a series of curved and tapering, interlacing electrodes 72, 76 arranged in parallel. A small focussing zone 74 on the active surface of the piezoelectric substrate 2 is indicated by a cross and is located near the transducer 70 but on an opposite lateral surface portion of the piezoelectric substrate 2.

FIGS. 10a and 10b show schematic illustrations of aerosol generators 1 according to other embodiments of the present disclosure.

The aerosol generator of FIG. 10a is similar to the aerosol generator 1 of FIGS. 1 and 2a, and like reference numerals are used to denote like features. The aerosol generator 1 shown in FIG. 4a differs from the aerosol generator 1 shown in FIGS. 1 and 2a in that the air inlets 4 are arranged to direct air into the chamber 8 away from the plane of the aerosol-generating element 2. The air inlets 4 are both oriented to direct air into the chamber at an angle α to the plane of the aerosol-generating element 2. The air inlets 4 are also oriented relative to the central longitudinal axis of the chamber, at an angle R. In this embodiment, angle α is about 30 degrees and the angle is about 60 degrees. By directing air into the chamber away from the aerosol-generating element, aerosolised aerosol-forming substrate generated in the chamber from the aerosol-generating element is encouraged to flow away from the aerosol-generating element, improving the rate of aerosol generation. In this embodiment, the air inlets are also formed by air passages, having a length. The air passages are shown extending into the chamber 8; however, it will be appreciated that in some embodiments, the air passages may not extend into the chamber 8.

The aerosol generator of FIG. 10b is similar to the aerosol generator 1 of FIG. 4a, and like reference numerals are used to denote like features. The aerosol generator 1 shown in FIG. 4b differs from the aerosol generator 1 shown in FIG. 4a in that the air inlets 4 are arranged to direct air into the chamber 8 away from the plane of the aerosol-generating element 2, as described above for FIG. 10a.

For the purpose of the present description and of the appended claims, except where otherwise indicated, all numbers expressing amounts, quantities, percentages and so forth, are to be understood as being modified in all instances by the term “about”. Also, all ranges include the maximum and minimum points disclosed and include any intermediate ranges therein, which may or may not be specifically enumerated herein. In this context, therefore, a number A is understood as A±{5%} of A. Within this context, a number A may be considered to include numerical values that are within general standard error for the measurement of the property that the number A modifies. The number A, in some instances as used in the appended claims, may deviate by the percentages enumerated above provided that the amount by which A deviates does not materially affect the basic and novel characteristic(s) of the claimed invention. Also, all ranges include the maximum and minimum points disclosed and include any intermediate ranges therein, which may or may not be specifically enumerated herein.

1.-15. (canceled)

16. An aerosol generator configured to generate an aerosol from an aerosol-forming substrate, the aerosol generator comprising:
a non-thermal aerosol-generating element configured to aerosolise an aerosol-forming substrate;
at least one air inlet;
at least one air outlet;
a chamber between the at least one air inlet and the at least one air outlet, the non-thermal aerosol-generating element being arranged in the chamber and being further configured to release aerosolised aerosol-forming substrate into the chamber;
an airflow path extending through the chamber between the at least one air inlet and the at least one air outlet, via the non-thermal aerosol-generating element; and
a side wall circumscribing the non-thermal aerosol-generating element, the side wall having a curved surface defining a curved surface of the chamber,
wherein the at least one air inlet extends through the side wall and is configured to direct air into the chamber in a direction tangential to the curved surface of the chamber.

17. The aerosol generator according to claim 16,
wherein the chamber comprises a mouth end and an aerosol-generation end opposite the mouth end,
wherein the at least one air outlet is arranged at the mouth end, and
wherein a width of the chamber at the mouth end is less than a width of the chamber at the aerosol-generation end.

18. The aerosol generator according to claim 17, wherein the non-thermal aerosol-generating element is arranged at the aerosol-generation end of the chamber.

19. The aerosol generator according to claim 16, wherein the at least one air inlet is configured to direct air around a periphery of the chamber.

20. The aerosol generator according to claim 16, wherein the chamber extends along a central longitudinal axis, and the at least one air inlet is configured to direct air into the chamber in a direction that does not intersect with the central longitudinal axis of the chamber.

21. The aerosol generator according to claim 16, wherein the non-thermal aerosol-generating element comprises a mesh element having a plurality of nozzles.

22. The aerosol generator according to claim 21, wherein the mesh aerosol-generating element is a vibratable mesh element configured to be oscillated.

23. The aerosol generator according to claim 22, further comprising an actuator coupled to the mesh and configured to oscillate the mesh aerosol-generating element.

24. The aerosol generator according to claim 21, further comprising an oscillation chamber having:
a cavity configured to contain a liquid to be aerosolised,
a liquid inlet configured to provide a supply of the liquid to be atomized to the cavity,
an elastically deformable element,
the mesh aerosol-generating element, and
an actuator arranged to oscillate the elastically deformable element,
wherein oscillation of the elastically deformable element by the actuator varies pressure inside the cavity.

25. The aerosol generator according to claim 23, wherein the actuator is a piezoelectric transducer.

26. The aerosol generator according to claim 16,
further comprising a surface acoustic wave atomizer (SAW-atomizer) comprising:
a substrate comprising an active surface, and
at least one transducer positioned on the active surface of the substrate and being configured to generate surface acoustic waves on the active surface of the substrate,
wherein the non-thermal aerosol-generating element forms the substrate.

27. The aerosol generator according to claim 16, wherein the non-thermal aerosol-generating element is a planar aerosol-generating element extending substantially in a plane.

28. The aerosol generator according to claim 27, wherein the at least one air inlet is configured to direct air into the chamber in a direction away from the planar aerosol-generating element.

29. A cartridge for an aerosol-generating system, the cartridge comprising:
a reservoir configured to hold a liquid aerosol-forming substrate;
a non-thermal aerosol generator according to claim 16; and
a liquid supply element configured to supply liquid from the reservoir to the non-thermal aerosol-generating element.

30. An aerosol-generating system configured to generate an aerosol from an aerosol-forming substrate, the aerosol-generating system comprising:
a reservoir configured to hold a liquid aerosol-forming substrate;
a non-thermal aerosol generator according to claim 16;
a liquid supply element configured to supply liquid from the reservoir to the non-thermal aerosol-generating element;
a power supply coupled to the aerosol generator and being configured to supply power to the aerosol generator; and
control circuitry configured to control a supply of power from the power supply to the aerosol generator.
